(19) United States
(12) Patent Application Publication
(10) Pub. No.: US 2017/0194210 A1
(43) Pub. Date: Jul. 6, 2017

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Tae-hwan OH, Goyang-si (KR); Kwang-sub YOON, Yongin-si (KR); Yong-chul JEONG, Suwon-si (KR); Seung-ho OH, Hwaseong-si (KR); Ji-young CHOI, Hwaseong-si (KR); Suk-won LEE, Ansan-si (KR); Woo-jeong SHIN, Seoul (KR); Myoung-ki JUNG, Suwon-si (KR); Min-jung KIM, Seoul (KR)

(21) Appl. No.: 15/292,157

(22) Filed: Oct. 13, 2016

(30) Foreign Application Priority Data
Dec. 30, 2015 (KR) 10-2015-0189451

(51) Int. Cl. H01L 21/8234; H01L 21/311; H01L 21/02; H01L 21/28; H01L 27/088

(52) U.S. Cl. CPC H01L 21/823456; H01L 21/28123; H01L 21/823431; H01L 27/0886; H01L 21/02112; H01L 21/02282; H01L 21/31138; H01L 29/42376

(57) ABSTRACT

A semiconductor device including a substrate including a first and second region; a first active region formed in an upper portion of the substrate in the first region; a second active region formed in an upper portion of the substrate in the second region; a first gate structure extending across the first active region, having a first gate length, and including a first high-k dielectric layer, a first lower metal layer, and a first upper metal layer; a second gate structure extending across the second active region, having a second gate length, and including a second high-k dielectric layer, a second lower metal layer having at least one metal layer, and a second upper metal layer; and spacers at sides of each of the first and second gate structures, a cross section of each of the first and second high-k dielectric layers has a U-shape, a cross section of each of the first and second lower metal layers has a U-shape, the first and second lower metal layers covering bottom surfaces and inner side surfaces of the corresponding first and second high-k dielectric layers, respectively, the first high-k dielectric and first lower metal layer are buried under the first upper metal layer, and the second high-k dielectric and second lower metal layer are buried under the second upper metal layer.

### CROSS-REFERENCE TO RELATED APPLICATION

Korean Patent Application No. 10-2015-0189451, filed on Dec. 30, 2015, in the Korean Intellectual Property Office, and entitled: “Semiconductor Device and Method of Manufacturing the Same,” is incorporated by reference herein in its entirety.

### BACKGROUND

1. Field

Embodiments relate to a semiconductor device and a method of manufacturing the same.

2. Description of the Related Art

Due to properties such as miniaturization, multiple functions, and/or low production costs, semiconductor devices have been in the spotlight as important factors in the electronics industry. The semiconductor devices may be divided into semiconductor memory devices for storing logic data, semiconductor logic devices for calculating logic data, hybrid semiconductor devices including memory elements and logic elements, and the like. As the electronics industry highly develops, a demand for properties of the semiconductor devices is gradually increasing. For example, a demand for high reliability, high speed, and/or multiple functions with respect to the semiconductor device is gradually increasing. In order to satisfy the demand for such properties, structures in the semiconductor devices are gradually becoming more complex, and the semiconductor devices are gradually becoming highly integrated.

### SUMMARY

Embodiments are directed to a semiconductor device and a method of manufacturing the same.

The embodiments may be realized by providing a semiconductor device including a substrate including a first region and a second region defined thereon; a first active region formed in an upper portion of the substrate in the first region; a second active region formed in an upper portion of the substrate in the second region; a first gate structure extending across the first active region, having a first gate length defined as a distance between a source and a drain, and including a first high-k dielectric layer, a first lower metal layer having at least one metal layer, and a first upper metal layer; a second gate structure extending across the second active region, having a second gate length that is at least two times the first gate length, and including a second high-k dielectric layer, a second lower metal layer having at least one metal layer, and a second upper metal layer; and spacers at both side surfaces of each of the first gate structure and the second gate structure, wherein a cross section of each of the first and second high-k dielectric layers, which cover an upper surface of the substrate and portions of side surfaces of the spacers, has a U-shape, a cross section of each of the first and second lower metal layers has a U-shape, the first and second lower metal layers covering bottom surfaces and inner side surfaces of the corresponding first and second high-k dielectric layers, respectively, the first high-k dielectric layer and the first lower metal layer are buried under the first upper metal layer, and the second high-k dielectric layer and the second lower metal layer are buried under the second upper metal layer.

The embodiments may be realized by providing a semiconductor device including a substrate including a first region and a second region defined thereon; at least one fin protruding from an upper surface of the substrate and extending in one direction; a first gate structure extending across the fin while surrounding an upper surface and side surfaces of the fin on the first region, having a first gate length defined as a distance between a source and a drain, and including a first high-k dielectric layer, a first lower metal layer having at least one metal layer, and a first upper metal layer; a second gate structure extending across the fin while surrounding an upper surface and side surfaces of the fin on the second region, having a second gate length that is at least two times the first gate length, and including a second high-k dielectric layer, a second lower metal layer having at least one metal layer, and a second upper metal layer; and spacers at both side surfaces of each of the first gate structure and the second gate structure, wherein a cross section of each of the first and second high-k dielectric layers, which cover the upper surface and the side surfaces of the fin and portions of side surfaces of each of the spacers, has a U-shape, a cross section of each of the first and second lower metal layers has a U-shape, wherein the first and second lower metal layers cover bottom surfaces and inner side surfaces of the corresponding first and second high-k dielectric layers, respectively, the first high-k dielectric layer and the first lower metal layer are buried under the first upper metal layer, and the second high-k dielectric layer and the second lower metal layer are buried under the second upper metal layer.

The embodiments may be realized by providing a method of manufacturing a semiconductor device, the method including forming a dummy gate structure extending in one direction on a substrate; forming spacers at both sidewalls of the dummy gate structure; forming an interlayer insulating layer covering the substrate and a result on the substrate, and planarizing the interlayer insulating layer to expose an upper surface of the dummy gate structure; removing the dummy gate structure, and sequentially forming a high-k dielectric layer, at least one metal layer, and a sacrificial layer on a portion in which the dummy gate structure is removed and on the interlayer insulating layer; leaving a portion of the sacrificial layer between the spacers by etching the sacrificial layer through ultraviolet (UV) irradiation, and exposing the at least one metal layer on side surfaces of the spacers and on the interlayer insulating layer; etching and removing portions of the exposed at least one metal layer and the high-k dielectric layer except for the portions covered by the sacrificial layer; removing the sacrificial layer, and forming a lower metal layer having the at least one metal layer, of which a cross section is buried as a U-shaped structure; and forming an upper metal layer on the lower metal layer and forming a gate structure.

The embodiments may be realized by providing a method of manufacturing a semiconductor device, the method including forming a trench by etching a substrate, forming a device isolation layer by filling a lower portion of the trench with an insulating material, and forming at least one fin protruding from the device isolation layer and extending in a first direction; forming a dummy gate structure extending in a second direction perpendicular to the first direction, covering a portion of the fin, and having a gate length defined as a distance between a source and a drain; forming spacers that extend in the second direction and that cover the portion of the fin on both side surfaces of the dummy gate structure; forming an interlayer insulating layer that covers the substrate and a result on the substrate, and planarizing the interlayer insulating layer to expose an upper surface of the dummy gate structure; removing the dummy gate structure, and sequentially forming a high-k dielectric layer, at least one metal layer, and a sacrificial layer on a portion in which the dummy gate structure is removed and on the interlayer insulating layer; leaving a portion of the sacrificial layer between the spacers by etching the sacrificial layer through ultraviolet (UV) irradiation, and exposing the at least one metal layer on side surfaces of the spacers and on the interlayer insulating layer; etching and removing portions of the exposed at least one metal layer and the high-k dielectric layer except for the portions covered by the sacrificial layer; removing the sacrificial layer, and forming a lower metal layer having the at least one metal layer, of which a cross section is buried as a U-shaped structure; and forming an upper metal layer on the lower metal layer and forming a gate structure.

The embodiments may be realized by providing a method of manufacturing a semiconductor device, the method including forming at least two dummy gate structures on a substrate, one dummy gate structure of the at least two dummy gate structures having a width that is different from a width of another dummy gate structure of the dummy gate structures; forming spacers at sidewalls of the at least two dummy gate structures; forming an interlayer insulating layer on the substrate having the spacers thereon; removing the at least two dummy gate structures to form at least two gate trenches; sequentially forming a high-k dielectric layer, at least one lower metal layer, and a sacrificial layer on the substrate and in the at least two gate trenches; partially removing the sacrificial layer by etching the sacrificial layer through ultraviolet (UV) irradiation such that a portion of the sacrificial layer remains in the at least two gate trenches; etching and removing portions of the at least one lower metal layer and the high-k dielectric layer that are uncovered by the sacrificial layer in the at least two gate trenches such that a structure having a U-shaped cross section remains in at least two gate trenches; removing the sacrificial layer; and forming an upper metal layer on the at least one lower metal layer such that at least two gate structures are respectively formed in the at least two gate trenches.

### BRIEF DESCRIPTION OF THE DRAWINGS

Features will be apparent to those of skill in the art by describing in detail exemplary embodiments with reference to the attached drawings in which:

FIG. 1 illustrates a plan view of a semiconductor device, in which a multi-threshold voltage is implemented, according to an embodiment;

FIGS. 2A and 2B illustrate cross-sectional views of the semiconductor device of FIG. 1;

FIGS. 3A and 3B illustrate cross-sectional views of effects of an etching method by ultraviolet (UV) irradiation according to an embodiment;

FIG. 4 illustrates cross-sectional views of a difference between a UV irradiation etching method according to an embodiment and a dry etching method;

FIGS. 5 to 8 illustrate cross-sectional views of semiconductor devices according to embodiments corresponding to FIG. 2A;

FIG. 9 illustrates a perspective view of a semiconductor device, in which a multi-threshold voltage is implemented, according to an embodiment;

FIGS. 10A and 10B illustrate cross-sectional views of the semiconductor device of FIG. 9;

FIGS. 11 to 14 illustrate cross-sectional views of semiconductor devices according to embodiments corresponding to FIG. 10A;

FIG. 15 illustrates a circuit diagram of a complementary metal-oxide-semiconductor (CMOS) inverter according to an embodiment;

FIG. 16 illustrates a circuit diagram of a CMOS static random-access memory (SRAM) device according to an embodiment;

FIGS. 17A to 17G illustrate cross-sectional views of stages in a process of manufacturing the semiconductor device of FIG. 2A;

FIG. 18 illustrates a cross-sectional view of a stage in a process of manufacturing the semiconductor device of FIG. 7; and

FIGS. 19A to 27C illustrate perspective views and cross-sectional views of stages in a process of manufacturing the semiconductor device of FIG. 9.

### DETAILED DESCRIPTION

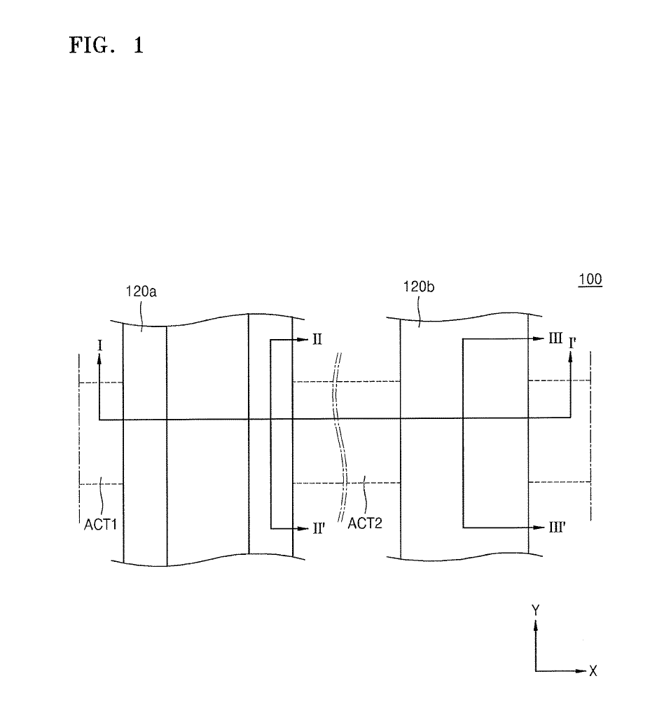

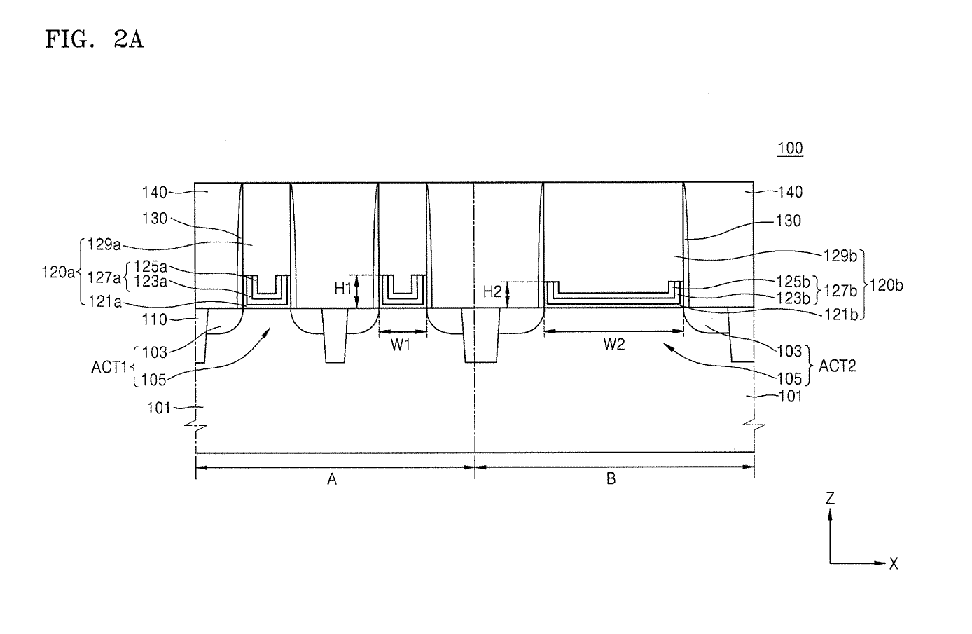

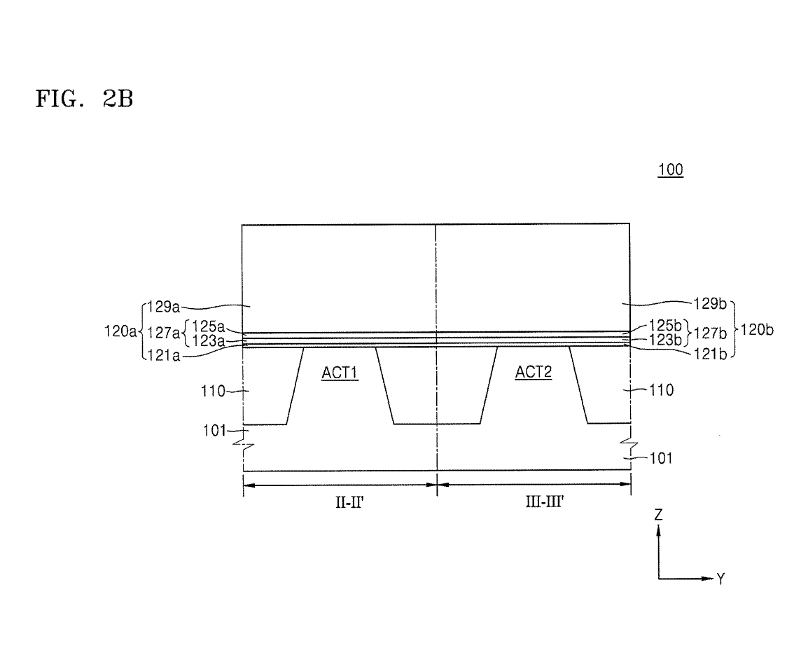

FIG. 1 illustrates a plan view of a semiconductor device, in which a multi-threshold voltage is implemented, according to an embodiment, FIG. 2A illustrates a cross-sectional view of a portion of the semiconductor device of FIG. 1 taken along line I-I′, and FIG. 2B illustrates a cross-sectional view of portions of the semiconductor device of FIG. 1 taken along lines and III-III′.

Referring to FIGS. 1 to 2B, a semiconductor device 100 may include a substrate 101 and gate structures 120a and 120b.

The substrate 101 may include a first region A and a second region B. First gate structures 120a may be disposed on the substrate 101 in the first region A and a second gate structure 120b may be disposed on the substrate 101 in the second region B. The first gate structures 120a and the second gate structure 120b may respectively constitute transistors disposed in the corresponding regions.

The first region A and the second region B may be regions connected to each other, or may be regions spaced apart from each other. In some embodiments, the first region A and the second region B may be regions for performing the same function. In other embodiments, the first region A and the second region B may be regions for performing different functions from each other. For example, the first region A may be a portion constituting a logic region, and the second region B may be another portion constituting the logic region. Further, in other embodiments, the first region A may be any one region of a memory region and a non-memory region, and the second region B may be the other region of the memory region and the non-memory region. In an implementation, the memory region may include a static random-access memory (SRAM) region, a dynamic RAM (DRAM) region, a flash memory region, a magnetic RAM (MRAM) region, a resistive RAM (RRAM) region, a phase-change RAM (PRAM) region, or the like, and the non-memory region may include a logic region.

The substrate 101 may be based on a silicon bulk wafer or a silicon-on-insulator (SOI) wafer. In an implementation, the substrate 101 may include a IV group semiconductor such as germanium (Ge) and the like, a IV-IV group compound semiconductor such as silicon germanium (SiGe), silicon carbide (SiC), and the like, or a III-V group compound semiconductor such as gallium arsenide (GaAs), indium arsenide (InAs), indium phosphide (InP), and the like. In an implementation, the substrate 101 may also be based on a SiGe wafer, an epitaxial wafer, a polished wafer, an annealed wafer, or the like.

The substrate 101 may be a P-type substrate or an N-type substrate. For example, the substrate 101 may be a P-type substrate including P-type impurity ions, or an N-type substrate including N-type impurity ions.

The substrate 101 may include active regions ACT1 and ACT2, which are defined through a device isolation layer 110 such as shallow trench isolation (STI) and the like, on an upper portion thereof. The active regions ACT1 and ACT2 may extend in a first direction (an X direction), and include a first active region ACT1 in the first region A and a second active region ACT2 in the second region B. Each of the active regions ACT1 and ACT2 may include a source/drain region 103 and a channel region 105. The source/drain region 103 may be an impurity region formed by implanting impurity ions, e.g., dopants, into the substrate 101 with a high concentration. For example, the source/drain region 103 may be formed by implanting dopants into the substrate 101 at both sides of each of the gate structures 120a and 120b with a high concentration of 1×10²⁰/cm³ or more. The channel region 105 may be formed between a source region and a drain region below each of the gate structures 120a and 120b.

The device isolation layer 110 may define the active regions ACT1 and ACT2 as described above, and may be formed to have a structure which surrounds the active regions ACT1 and ACT2. Further, the device isolation layer 110 may be disposed between the active regions ACT1 and ACT2 to electrically separate the active regions. The device isolation layer 110 may be formed to have identical structures and identical sizes in the first region A and the second region B. In an implementation, the device isolation layer 110 may also be formed to have different structures and different sizes in the first region A and the second region B. For example, the device isolation layer 110 may be formed to have a structure in the second region B deeper and wider than that in the first region A. The device isolation layer 110 may include, e.g., at least one of a silicon oxide film, a silicon nitride film, a silicon oxynitride film, and a combination thereof.

Each of the gate structures 120a and 120b may extend in a second direction (a Y direction) across the corresponding active regions ACT1 and ACT2 on the substrate 101. The gate structures 120a and 120b may include the first gate structures 120a in the first region A and the second gate structure 120b in the second region B. The first gate structures 120a may be on the substrate 101 across the first active region ACT1, and the second gate structure 120b may be on the substrate 101 across the second active region ACT2.

In FIG. 1, although the gate structures 120a and 120b are respectively disposed by perpendicularly crossing the corresponding active regions ACT1 and ACT2, the gate structures 120a and 120b may cross the corresponding active regions ACT1 and ACT2 at an angle which is not perpendicular thereto. In an implementation, a single first gate structure 120a crosses a single first active region ACT1 and a single second gate structure 120b crosses a single second active region ACT2. In an implementation, a plurality of first gate structures 120a may cross a single first active region ACT1, and a plurality of second gate structures 120b may cross a single second active region ACT2. In an implementation, a single first gate structure 120a may also cross a plurality of first active regions ACT1, and a single second gate structure 120b may also cross a plurality of second active regions ACT2. In an implementation, the first active region ACT1 in the first region A and the second active region ACT2 in the second region B may extend in the same first direction (the X direction), but may also extend in different directions. In an implementation, the first gate structure 120a in the first region A and the second gate structure 120b in the second region B may also extend in different directions.

In the semiconductor device 100 in the present embodiment, the gate structures 120a and 120b may be formed to have a replacement metal gate (RMG) structure. The RMG structure, which is a structure in which the source/drain region 103 is formed using a dummy gate structure and then a metal gate is formed on a portion in which the dummy gate is removed, is referred to as a gate-last structure.

Spacers 130 may be formed on both side surfaces of each of the gate structures 120a and 120b. In an implementation, the spacers 130 may be surrounded by an interlayer insulating layer 140. The spacers 130 may be formed of an insulating material such as a nitride film or an oxynitride film. For example, the spacers 130 may be formed of a silicon nitride film or a silicon oxynitride film. In an implementation, the spacers 130 may also be formed in an L shape. In an implementation, the spacers 130 may be formed in a single layer or the spacers 130 may also be formed in multiple layers.

Meanwhile, the interlayer insulating layer 140 may be formed on the substrate 101 as a portion in which the gate structures 120a and 120b and the spacers 130 do not exist or are not present. Accordingly, the interlayer insulating layer 140 may have a structure which surrounds side surfaces of each of the spacers 130, and the spacers 130 may be interposed between the gate structures 120a and 120b and the interlayer insulating layer 140. Such an interlayer insulating layer 140 may include at least one of a silicon oxide film, a silicon nitride film, a silicon oxynitride film, and a combination thereof, and may be formed of a material having a different etch selectivity from that of the spacers 130.

The first gate structure 120a in the first region A may have a first gate length W1, and the second gate structure 120b in the second region B may have a second gate length W2. The gate length may be defined as a distance between a source and a drain, and used in substantially the same sense as a channel length. The first gate length W1 may be smaller than the second gate length W2. In an implementation, the second gate length W2 may be at least two times the first gate length W1. In an implementation, the second gate length W2 may be at least five times the first gate length W1.

In an implementation, two first gate structures 120a may be disposed in the first region A, and a single second gate structure 120b may be disposed in the second region B. In an implementation, one or three or more first gate structures 120a may be disposed in the first region A. In an implementation, two or more second gate structures 120b may be disposed in the second region B. Meanwhile, the first gate structure 120a may be disposed in the first region A with a dense density, and the second gate structure 120b may be disposed in the second region B with a sparse density. Here, the dense density and the sparse density may be defined as the numbers of the disposed gate structures per unit area, and a density of a large-sized gate structure may generally be small.

The gate lengths of the first gate structure 120a and the second gate structure 120b may be different as described above. Further, as described below, a structure of layers constituting each of the first gate structure 120a and the second gate structure 120b may be slightly different from each other due to a difference between the gate lengths.

In the following description, when elements are not clearly differentiated into a first element and a second element, an element having a reference numeral to which a character ‘a’ is attached may refer to a gate structure formed in the first region A or a constituent layer thereof, and an element having a reference numeral to which a character ‘b’ is attached may refer to a gate structure formed in the second region B or a constituent layer thereof.

The first gate structure 120a may include a first high-k dielectric layer 121a, a first lower metal layer 127a, and a first upper metal layer 129a. The first high-k dielectric layer 121a may have a buried U-shaped structure as illustrated in FIG. 2A, and may have a buried structure covered by the first lower metal layer 127a and the first upper metal layer 129a. In an implementation, the first high-k dielectric layer 121a may have a U-shaped structure, and an upper surface thereof may be exposed by extending upwardly along a side surface of the spacer 130.

The first high-k dielectric layer 121a may also be referred to as a high-k layer, and may be formed of a dielectric material having a high dielectric constant (k). In an implementation, the high-k dielectric layer 121a may be formed of a hafnium-based (Hf-based) material or a zirconium-based (Zr-based) material. For example, the high-k dielectric layer 121a may include hafnium dioxide (HfO₂), hafnium silicon oxide (HfSiO), hafnium silicon oxynitride (HfSiON), hafnium oxynitride (HfON), hafnium aluminum oxide (HfAlO), hafnium lanthanum oxide (HfLaO), zirconium dioxide (ZrO₂), zirconium silicon oxide (ZrSiO), and the like.

In an implementation, the first high-k dielectric layer 121a may include, e.g., lanthanum oxide (La₂O₃), lanthanum aluminum oxide (LaAlO₃), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc_{0.5}Ta_{0.5}O₃), lead zinc niobate (PbZnNbO₃), and the like. Such a high-k dielectric layer 121a may be formed through various deposition methods such as an atomic layer deposition (ALD) method, a chemical vapor deposition (CVD) method, a physical vapor deposition (PVD) method, and the like.

The first high-k dielectric layer 121a may include a thin interfacial layer thereunder. The thin interfacial layer may be formed on the substrate 101, and may be formed of an insulating material such as an oxide film, a nitride film, or an oxynitride film. For example, the thin interfacial layer may be formed of silicon dioxide (SiO₂) or silicon oxynitride (SiON).

The first lower metal layer 127a may be formed on the first high-k dielectric layer 121a, and may have a buried U-shaped structure like the first high-k dielectric layer 121a. In an implementation, the first lower metal layer 127a may have a buried structure covered by the first upper metal layer 129a. The first lower metal layer 127a may include at least one metal layer. In an implementation, the first lower metal layer 127a may include a first metal layer 123a and a second metal layer 125a.

The first lower metal layer 127a may include at least one of titanium (Ti) and tantalum (Ta). In an implementation, the first lower metal layer 127a may be formed of a metal-nitride, a metal-carbide, a metal-silicide, a metal-silicon-nitride, and a metal-silicon-carbide series, or the like, which contain at least one of Ti and Ta. In an implementation, the first metal layer 123a, which is a lower layer of the first metal layer 123a and the second metal layer 125a constituting the first lower metal layer 127a, may include TaN, and the second metal layer 125a, which is an upper layer thereof, may include TiN.

In an implementation, the first lower metal layer 127a may be formed through various deposition methods such as an ALD method, a CVD method, a PVD method, and the like, and may be formed to have a relatively small thickness. In an implementation, the first lower metal layer 127a may be formed to have a thickness of several nm or less.

The first lower metal layer 127a may constitute a metal electrode of the first gate structure 120a with the first upper metal layer 129a, and may function to adjust a work function of the metal electrode. Accordingly, the first lower metal layer 127a may also be referred to as a work-function adjusting layer. The first lower metal layer 127a may perform a work-function adjustment function by changing a material, a thickness, a size, a number of layers, a structure, or the like.

As described above, the first lower metal layer 127a may have the U-shaped structure. Based on the U-shaped structure, heights of protruding portions at both side surfaces of the first lower metal layer 127a may have a first height H1 from an upper surface of the substrate 101. In an implementation, the first height H1 may be in a range of several nm to several tens of nm. In the semiconductor device 100 in the present embodiment, the work-function adjustment function of the first lower metal layer 127a may be related to the U-shaped structure. The work-function adjustment function of the first lower metal layer 127a will be described below along with a second lower metal layer 127b.

The first lower metal layer 127a may help prevent atoms or ions of the first high-k dielectric layer 121a thereunder from being diffused into the first upper metal layer 129a along with the work-function adjustment function. In an implementation, the first lower metal layer 127a may also facilitate the deposition of the first upper metal layer 129a.

The first upper metal layer 129a may be formed on the first high-k dielectric layer 121a and the first lower metal layer 127a to have a structure which covers the first high-k dielectric layer 121a and the first lower metal layer 127a. As a cross section of each of the first high-k dielectric layer 121a and the first lower metal layer 127a have a U-shaped structure, a cross section of the first upper metal layer 129a may have a, e.g., T-shaped structure. In an implementation, the first upper metal layer 129a may be formed to have a structure which covers only the first lower metal layer 127a and not the first high-k dielectric layer 121a.

The first upper metal layer 129a may be formed of an N-type metal or a P-type metal. For reference, the N-type metal may be referred to as a metal constituting a gate electrode of an N-channel metal oxide semiconductor (NMOS) transistor, and the P-type metal may be referred to as a metal constituting a gate electrode of a P-channel MOS (PMOS) transistor. When the first upper metal layer 129a is formed of the N-type metal, the first upper metal layer 129a may include Ti or Ta. In an implementation, the first upper metal layer 129a may include TiN or TaN. In an implementation, the first upper metal layer 129a may include an Al compound containing Ti or Ta. In an implementation, the first upper metal layer 129a may include, e.g., an Al compound such as TiAlC, TiAlN, TiAlC—N, TiAl, and the like, or an Al compound such as TaAlC, TaAlN, TaAlC—N, TaAl, and the like. In an implementation, the first upper metal layer 129a of the N-type metal may be formed as two or more layers rather than a single layer.

When the first upper metal layer 129a is formed of the P-type metal, the first upper metal layer 129a may include, e.g., at least one of Mo, Pd, Ru, Pt, TiN, WN, TaN, Ir, TaC, RuN, and MoN. In an implementation, the first upper metal layer 129a as the P-type metal may be formed in two or more layers rather than a single layer.

In the semiconductor device 100 in the present embodiment, the first upper metal layer 129a may be formed of the N-type metal. In an implementation, in the semiconductor device 100 in the present embodiment, the first upper metal layer 129a may include, e.g., TiN.

The second gate structure 120b may include a second high-k dielectric layer 121b, the second lower metal layer 127b, and a second upper metal layer 129b. As described above, the second gate length W2 of the second gate structure 120b may be greater than the first gate length W1 of the first gate structure 120a. Therefore, widths of the second high-k dielectric layer 121b, the second lower metal layer 127b, and the second upper metal layer 129b in the first direction (the X direction) may be respectively greater than widths of the first high-k dielectric layer 121a, the first lower metal layer 127a, and the first upper metal layer 129a in the first direction (the X direction).

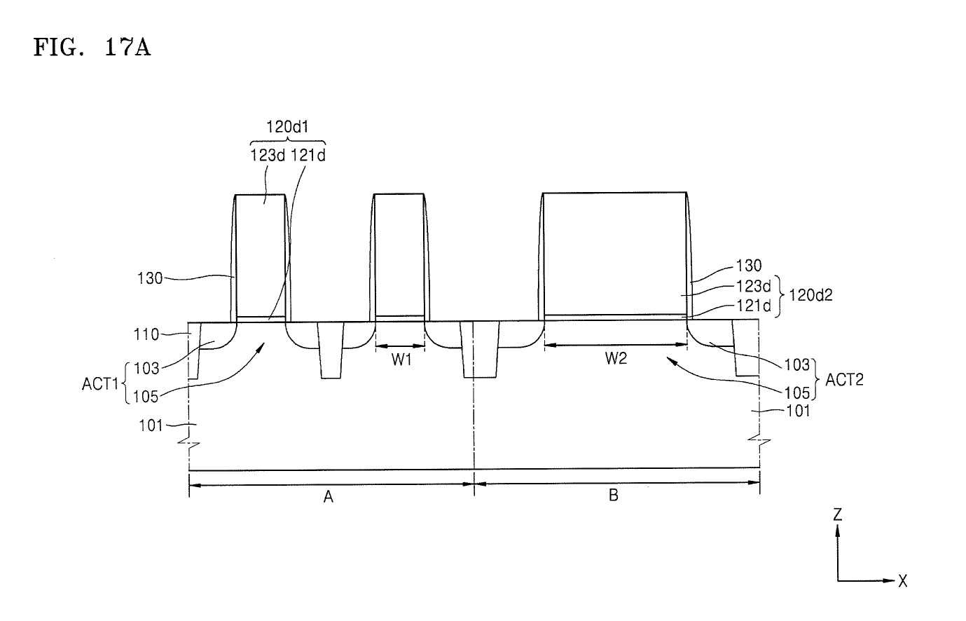

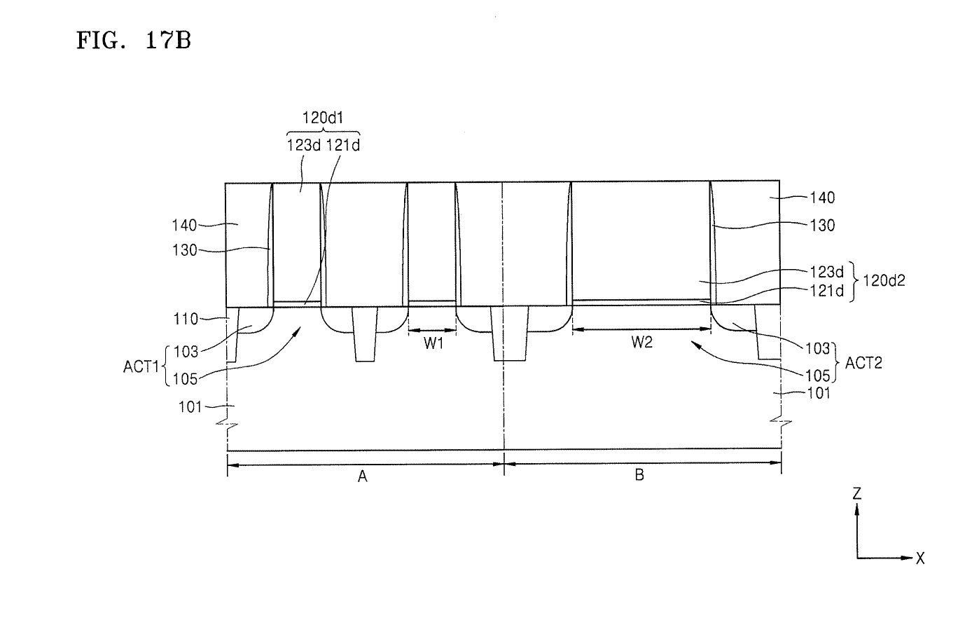

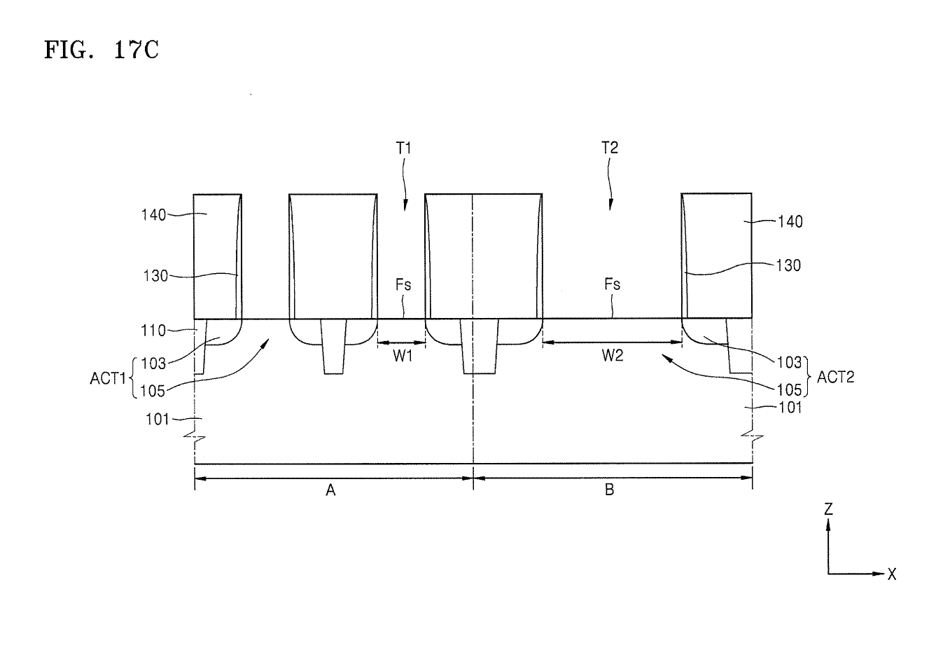

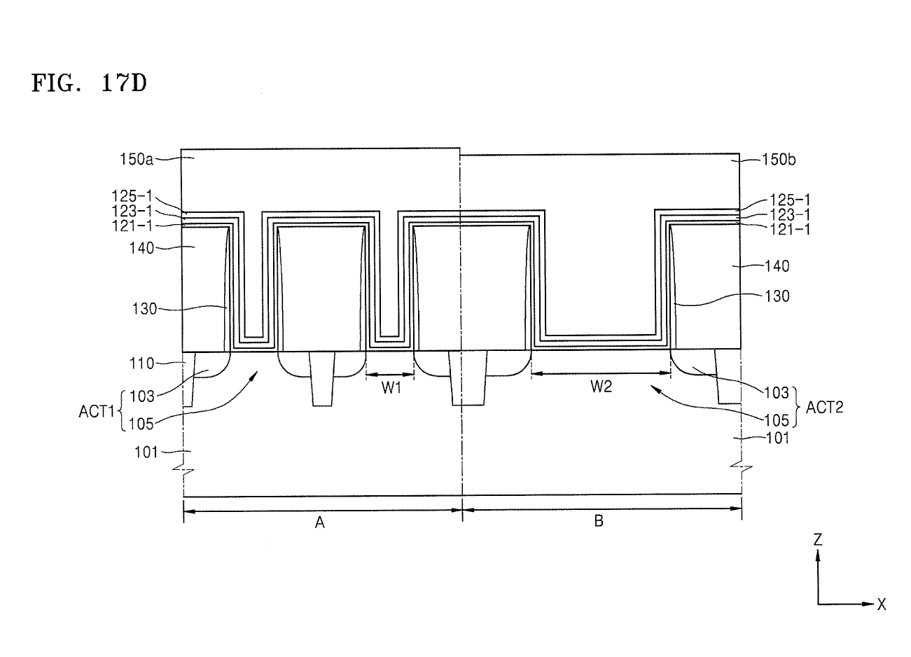

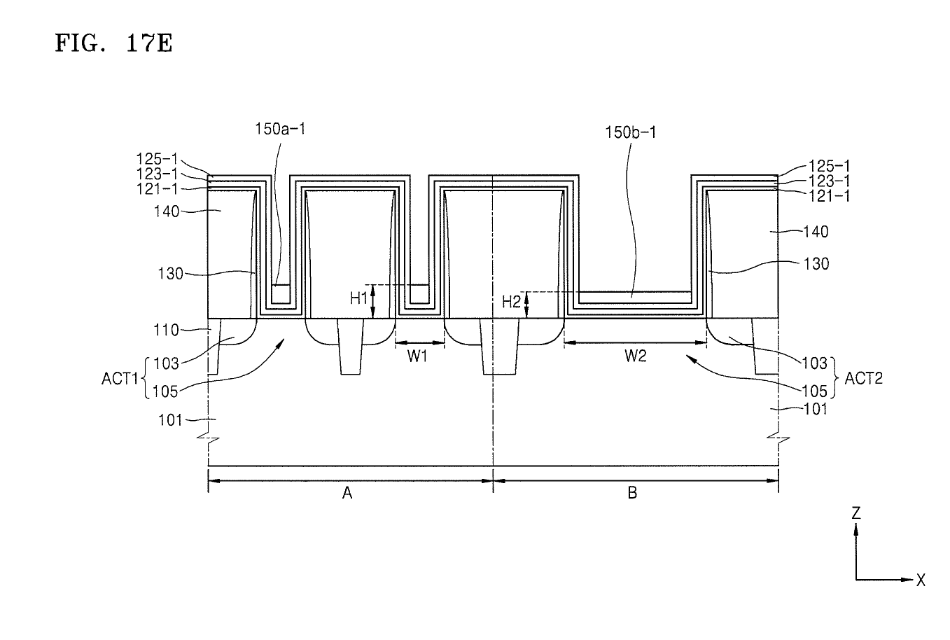

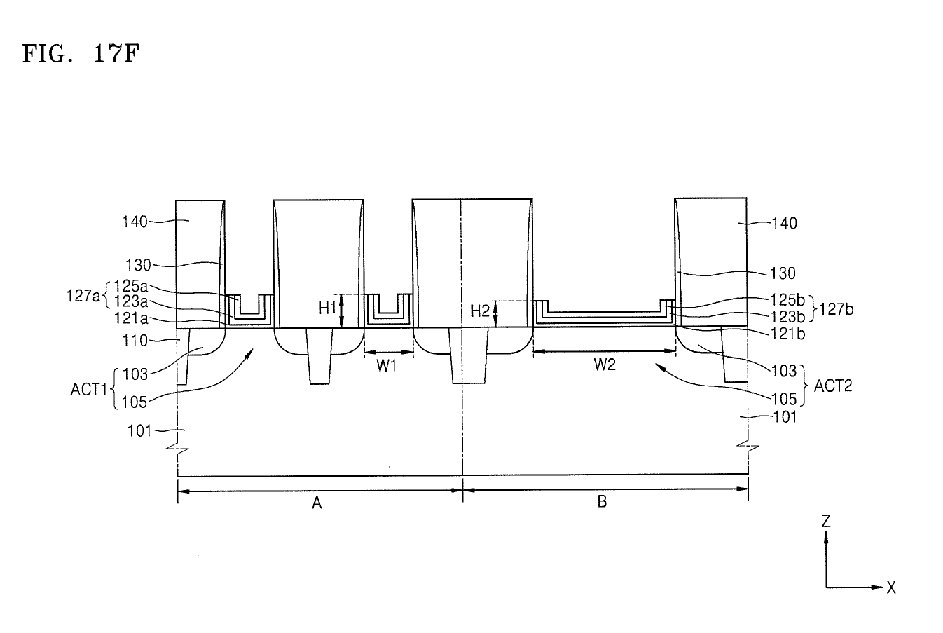

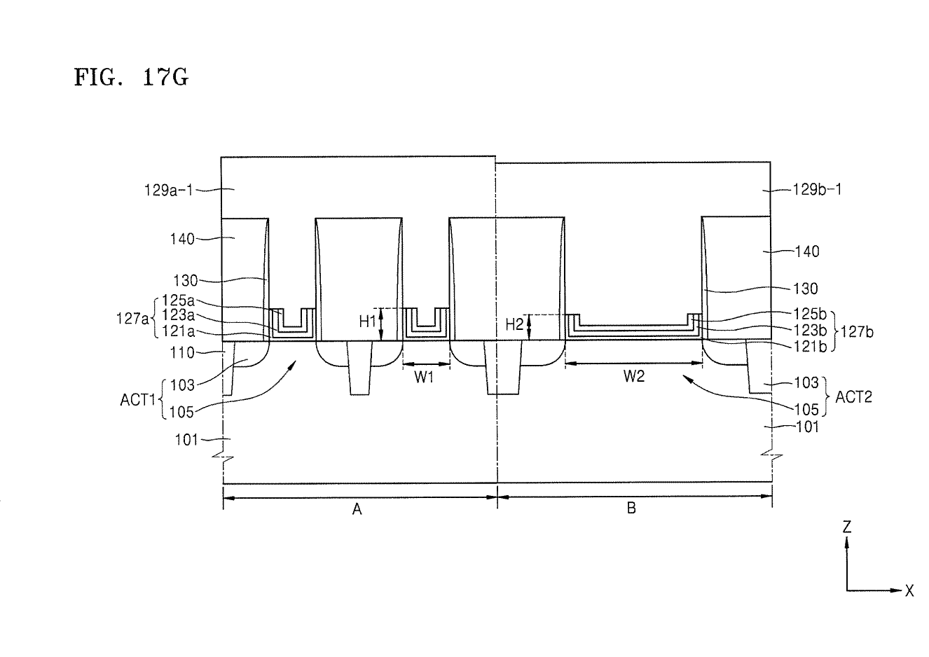

The second lower metal layer 127b may also have a buried U-shaped structure. In an implementation, heights of protruding portions at both side surfaces of the second lower metal layer 127b having the U-shaped structure may have a second height H2 from the upper surface of the substrate 101. In an implementation, the second height H2 may be the same as the first height H1. In an implementation, the second height H2 may also be smaller than the first height H1. The first height H1 of the first lower metal layer 127a and the second height H2 of the second lower metal layer 127b will be described in more detail in descriptions of FIGS. 17A to 17G.

Respective thicknesses of the second high-k dielectric layer 121b, the second lower metal layer 127b, and the second upper metal layer 129b may be substantially the same as respective thicknesses of the first high-k dielectric layer 121a, the first lower metal layer 127a, and the first upper metal layer 129a. In an implementation, the thicknesses of the second high-k dielectric layer 121b, the second lower metal layer 127b and the second upper metal layer 129b may also be respectively different from the thicknesses of the first high-k dielectric layer 121a, the first lower metal layer 127a and the first upper metal layer 129a.

In addition, structures, materials, functions, and the like of the second high-k dielectric layer 121b, the second lower metal layer 127b, and the second upper metal layer 129b may be the same as those described for the first high-k dielectric layer 121a, the first lower metal layer 127a, and the first upper metal layer 129a. In an implementation, in the semiconductor device 100 in the present embodiment, the second lower metal layer 127b may include a first metal layer 123b of TaN and a second metal layer 125b of TiN. In an implementation, the second upper metal layer 129b may include TiN.

In the semiconductor device 100 in the present embodiment, the first gate structure 120a and the second gate structure 120b may be simultaneously formed, and the corresponding layers thereof may be simultaneously formed through a single process. For example, the first high-k dielectric layer 121a, the first lower metal layer 127a, and the first upper metal layer 129a of the first gate structure 120a may be formed at the same time as the second high-k dielectric layer 121b, the second lower metal layer 127b, and the second upper metal layer 129b of the second gate structure 120b, respectively. Accordingly, the layers of the first gate structure 120a may be formed of the same materials as the corresponding layers of the second gate structure 120b.

In the semiconductor device 100 in the present embodiment, the lower metal layers 127a and 127b having the buried U-shaped structure may be used in the gate structures 120a and 120b, respectively, and threshold voltages of transistors may be very finely adjusted. When the lower metal layers 127a and 127b are formed to have the U-shaped structure, contact areas between the lower metal layers 127a and 127b and the upper metal layers 129a and 129b may be changed, e.g., reduced, and thus an amount of moving electrons may be reduced. Therefore, changes of the work functions of the upper metal layers 129a and 129b by the lower metal layers 127a and 127b may be minimized, and the threshold voltages may be finely adjusted due to the minimal changes of the work functions.

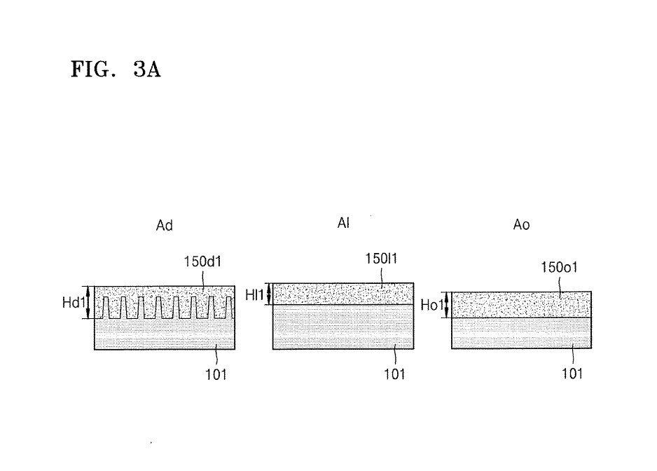

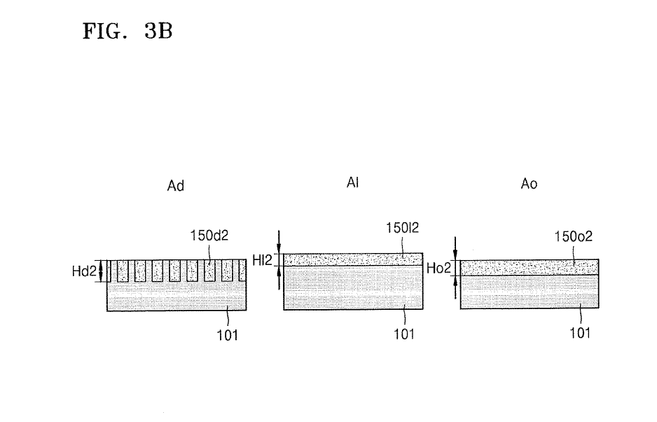

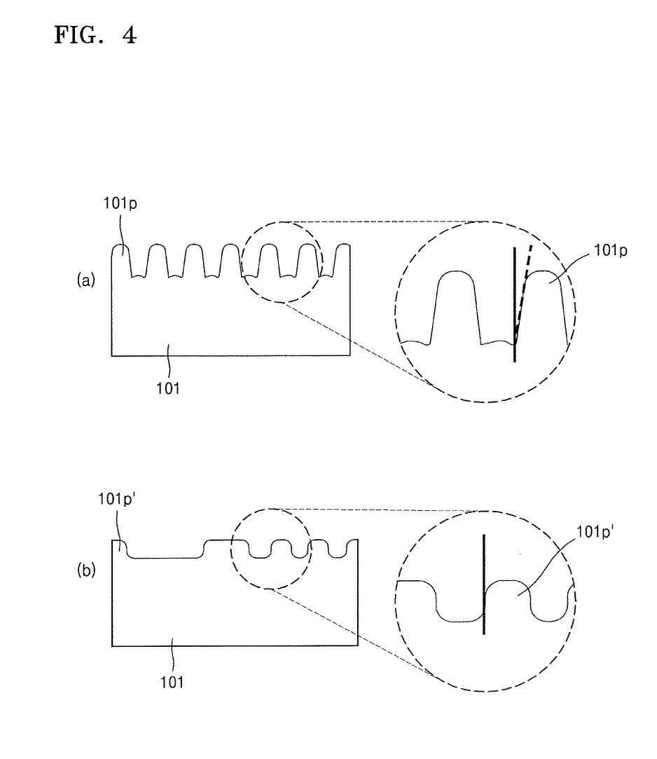

If the lower metal layers 127a and 127b having the buried U-shaped structure are formed to have a uniform height to some extent, the threshold voltages in the gate structures having various gate lengths may be uniformly adjusted according to the gate lengths. In the semiconductor device 100 in the present embodiment, as sacrificial layers 150a, 150b, etc. (see FIG. 17D) used to form the lower metal layers 127a and 127b are removed to a uniform thickness by being etched through ultraviolet (UV) irradiation, the lower metal layers 127a and 127b may be formed to have a U-shaped structure with a uniform height. Therefore, in the semiconductor device 100 in the present embodiment, due to the lower metal layers 127a and 127b having the buried U-shaped structure, transistors having various threshold voltages in which each threshold voltage is uniform and a semiconductor device including such transistors may be easily implemented. The etching of the sacrificial layers through UV irradiation will be described in more detail in descriptions of FIGS. 3A to 4B.

For example, in the semiconductor device 100 in the present embodiment, the layers of the first gate structure 120a may be formed of the same material as the corresponding layers of the second gate structure 120b, and the gate length of the first gate structure 120a may be formed differently from the gate length of the second gate structure 120b. Therefore, the threshold voltages of the transistors formed with the first gate structure 120a and the second gate structure 120b may be different. For reference, in general, when transistors have different sizes and identical gate structures, a threshold voltage of a transistor having a small gate length, e.g., a small channel length, may be lower than that of the other transistors.

In an implementation, in the semiconductor device 100 in the present embodiment, a case in which the layers of the first gate structure 120a are formed of different materials from the corresponding layers of the second gate structure 120b is not intended to be excluded. When the layers of the first gate structure 120a are formed of different material from the corresponding layers of the second gate structure 120b, the threshold voltages of the first gate structure 120a and the second gate structure 120b may be changed in more various ways. For example, when the first upper metal layer 129a of the first gate structure 120a and the second upper metal layer 129b of the second gate structure 120b are formed of materials having different work functions, the threshold voltages thereof may be different from those in the case of being formed of the same material. The formation of the corresponding layers together through a single process may be advantageous in process efficiency and cost, and the materials of the corresponding layers may be determined in consideration of the overall process efficiency, cost, a variety of required threshold voltages, and the like.

For reference, a threshold voltage (Vth) of a transistor may be calculated by the following Equation (1).

Vth=φms−(Qox+Qd)/Cox+2φf Equation (1)

Here, φms may refer to a potential difference between a work function of a metal constituting a gate and a work function of a semiconductor constituting a channel, Qox may refer to a fixed charge at a surface of a gate oxide film, Qd may refer to a positive charge at an ion layer, Cox may refer to capacitance of a gate per unit area, and φf may refer to a potential difference between an intrinsic or unique Fermi level (Ei) and a Fermi level (Ef) of a semiconductor.

According to Equation (1), the following methods may be performed to adjust a threshold voltage. A first method is a method of adjusting φms. A second method is a method of adjusting Qox. A third method is a method of adjusting φf.

For example, the first method may be implemented by doping a semiconductor with ions or by applying a metal having a corresponding work function to the gate. For example, a difference between work functions of the semiconductor and the metal may be increased or decreased by increasing or decreasing the work function of the semiconductor by doping the semiconductor with ions. In an implementation, the difference between the work functions of the semiconductor and the metal may be increased or decreased by using a metal having the corresponding work function.

The second method may be achieved by increasing or decreasing a value of Qox, and Vth may be decreased when the value of Qox is decreased and Vth may be increased when the value of Qox is increased according to Equation (1). The second method is represented as Qox=∈₀∈_{R}/tₒₓ, here because ∈_{R} is a dielectric constant of a gate oxide film and tₒₓ is a thickness of the gate oxide film, and increasing the thickness of the gate oxide film or using a material having a low dielectric constant is sufficient when the value of Qox needs to be decreased. The third method may also be achieved by doping the semiconductor with ions. For example, when a semiconductor layer is formed with a P-type substrate, φf may be increased by doping the semiconductor layer with arsenic (As).

As the semiconductor device is highly integrated, a scaling of a channel region is increased. Accordingly, in a method of doping with ions, dispersion degradation of threshold voltages due to a non-uniform distribution of dopants and degradation of mobility according to increasing a dopant concentration in the channel region may occur, and thus degradation of a reliability and performance of the semiconductor device may occur. Accordingly, there may be a limit in a method of adjusting a threshold voltage through ion doping. Further, in a method of using a metal having a corresponding work function, when transistors having various threshold voltages, e.g., a plurality of MOSFETs having different threshold voltages, need to be implemented in a logic device, problems in that securing an etch selectivity is difficult when different metal layers are patterned, a lower gate oxide film is damaged while patterning the metal layer, and the like may occur.

In an implementation, a threshold voltage may be adjusted by forming a metal electrode of a gate with several metal layers having different work functions. For example, like the gate structures 120a and 120b of the semiconductor device 100 in the present embodiment, the threshold voltage may be adjusted by forming a metal electrode as multiple layers of the lower metal layers 127a and 127b and the upper metal layers 129a and 129b. A method of adjusting the threshold voltages may be a part of a method of using a metal having a corresponding work function by forming a metal electrode with several metal layers in this way. In an implementation, in the gate structures 120a and 120b of the semiconductor device 100 in the present embodiment, threshold voltages of the gate structures 120a and 120b may be uniformly changed according to gate lengths by uniformly forming the lower metal layers 127a and 127b to have a buried U-shaped structure. The method of adjusting the threshold voltages based on the lower metal layers 127a and 127b having the buried U-shaped structure is also a method of changing the work function of the metal electrode, and the method of adjusting the threshold voltages may also be a part of the method of using the metal having the corresponding work function.

In the semiconductor device 100 in the present embodiment, transistors having different threshold voltages in which each threshold voltage is uniform may be implemented by applying the lower metal layers 127a and 127b having the buried U-shaped structure to the gate structures 120a and 120b. For example, in the semiconductor device 100 in the present embodiment, the gate structures 120a and 120b may include the lower metal layers 127a and 127b having the buried U-shaped structure with a uniform height to some extent, and the threshold voltages of the corresponding transistors may be uniformly adjusted and determined according to the gate lengths. For example, although the threshold voltages of the transistors are different when the gate lengths may be different, uniformity in which transistors have the same threshold voltage when the gate lengths are the same may be provided.

Therefore, in the semiconductor device 100 in the present embodiment, due to the lower metal layers 127a and 127b having the buried U-shaped structure, transistors having various threshold voltages in which each threshold voltage is uniform and a semiconductor device including such transistors, e.g., a logic device, may be easily implemented.

In an implementation, in the semiconductor device 100 in the present embodiment, the corresponding layers of the first gate structure 120a and the second gate structure 120b may be simultaneously formed through a single process. Therefore, in implementing a semiconductor device including transistors having various threshold voltages, it may be advantageous in terms of cost and manufacturing process.

FIGS. 3A and 3B illustrate cross-sectional views of effects of an etching method by UV irradiation according to an embodiment. ‘Ad’ represents a region in which silicon structures are densely disposed, ‘Al’ represents a region in which large-sized silicon structures are sparsely disposed, and ‘Ao’ represents an open region in which no silicon structures are disposed.

Referring to FIGS. 3A and 3B, as illustrated in FIG. 3A, a substrate 101 may be coated with organic thin films 150d1, 150l1, and 150o1 with predetermined heights. The substrate 101 may be, for example, a silicon substrate. Silicon structures such as fins protruding from an upper surface of the substrate 101 may be formed in an ‘Ad’ region or an ‘Al’ region. Meanwhile, one entire silicon structure is illustrated in the ‘Al’ region, and thus, the upper surface of the substrate 101 in the ‘Al’ region may be higher than the upper surface of the substrate 101 in the ‘Ad’ region or an ‘Ao’ region.

The organic thin films 150d1, 150l1, and 150o1, which are material layers containing a large amount of carbon, may be removed by being etched through ozonolysis by UV irradiation. For example, the organic thin films may be formed as a spin on hardmask (SOH). The SOH may be a material layer made of a hydrocarbon compound having a relatively high carbon content of, e.g., about 85% to 99% by weight based on a total weight or a derivative thereof. Etching rates of such organic thin films 150d1, 150l1, and 150o1 may be changed by irradiation intensity, irradiation time, and the like of UV. In an implementation, the etching rates may be changed by content of components of the organic thin films 150d1, 150l1, and 15001.

In an implementation, even when the substrate 101 in the ‘Ad,’ ‘Al,’ and ‘Ao’ regions is respectively coated with the organic thin films 150d1, 150l1, and 150o1 under the same conditions, final heights of the organic thin films 150d1, 150l1, and 150o1 in respective regions may be different due to a loading effect. For example, when the substrate 101 is coated with the organic thin films 150d1, 150l1, and 15001 under the same conditions using a spin coating or other depositing processes, initial heights Hd1, Hl1, and Ho1 of the organic thin films 150d1, 150l1, and 150o1 respectively coated in the ‘Ad,’ ‘Al,’ and ‘Ao’ regions may be different. For example, when the initial height Ho1 in the ‘Ao’ region is about 100 nm, the initial height Hd1 in the ‘Ad’ region may be about 135 nm and the initial height Hl1 in the ‘Al’ region may be about 85 nm.

When a dry etching method is performed on the organic thin films 150d1, 150l1, and 150o1 under the same process conditions, respective thicknesses to be etched in the ‘Ad,’ ‘Al,’ and ‘Ao’ regions may also be different due to the loading effect. When the organic thin films 150d1, 150l1, and 150o1 are etched through UV irradiation, unlike the dry etching method, the organic thin films 150d1, 150l1, and 150o1 may be etched with the same thickness without the loading effect.

FIG. 3B illustrates etching results through such UV irradiation. For example, after the etching through the UV irradiation, final heights Hd2, H12, and Ho2 of the organic thin films 150d2, 15012, and 150o2 respectively remaining in the ‘Ad,’ ‘Al,’ and ‘Ao’ regions may be different. For example, when the final height Ho2 in the ‘Ao’ region is about 70 nm, the final height Hd2 in the ‘Ad’ region may be about 105 nm and the final height H12 in the ‘Al’ region may be about 55 nm. In the respective ‘Ad,’ ‘Al,’ and ‘Ao’ regions, although the final heights Hd2, H12, and Ho2 may be different, the etched thicknesses may be substantially the same as about 30 nm. For example, using the etching method by UV irradiation, the organic thin films 150d1, 150l1, and 150o1 may be etched with the same thickness (e.g., the same amount may be removed) without the loading effect.

In an implementation, in order to uniformly etch material layers in regions having different pattern densities with identical thicknesses, a method of forming the corresponding material layers of an organic thin film such as an SOH and etching the corresponding material layers by UV irradiation may be applied. For example, in the semiconductor device 100 (see FIG. 2A) in the present embodiment, the lower metal layers 127a and 127b (see FIG. 2A) having the buried U-shaped structure may be formed using sacrificial layers 150a and 150b (see FIG. 17D), and the sacrificial layers may be etched to the same thickness (e.g., the same amount may be removed) regardless of the pattern density in order to form the lower metal layers 127a and 127b (see FIG. 2A) having the U-shaped structure having uniform heights. In the semiconductor device in the present embodiment, in order to implement the uniform heights of the lower metal layers 127a and 127b (see FIG. 2A) having the buried U-shaped structure, the sacrificial layers may be formed with the organic thin films such as an SOH, and the sacrificial layers may be etched by UV irradiation.

FIG. 4 illustrates cross-sectional views illustrating a difference between a UV irradiation etching method according to an embodiment and a dry etching method. Drawing (a) illustrates a result according to the dry etching method and drawing (b) illustrates a result according to the UV irradiation etching method.

Referring to FIG. 4, in drawing (a), a substrate 101 in which protruding portions are formed on an upper surface thereof is prepared, and the substrate 101 may be coated with an organic thin film as illustrated in FIG. 3A. The substrate 101 may be, e.g., a silicon substrate. Then, the organic thin film may be removed by a dry etching method. As illustrated in the enlarged view, after the performing of the dry etching method, side surfaces of each of protruding portions 101p may have a predetermined gradient. Such a gradient may be generated by etching upper portions of the protruding portions 101p by the dry etching method. The gradients of side surfaces of each protruding portion 101p may be undesirable results, and thus, may correspond to a kind of damage caused by the dry etching method.

In drawing (b), a substrate 101 in which protruding portions are formed on an upper surface thereof is also prepared, the substrate 101 may be coated with an organic thin film, and the organic thin film may be removed by the UV irradiation etching method. As illustrated in the enlarged view, even after the etching by UV irradiation, side surfaces of protruding portions 101p′ may be maintained in a vertical state. For example, the UV irradiation etching method may not cause damage to the protruding portions 101p′. Further, the UV irradiation etching method may not cause damage on the upper surface of the substrate 101 as well as the protruding portions 101p′.

Furthermore, the UV irradiation etching method may also not cause damage on material layers other than the organic thin film. Therefore, the organic thin film may be etched to a uniform thickness by the UV irradiation etching method regardless of the pattern density, while the UV irradiation etching method may not cause damage to the substrate 101 and the other material layers. In an implementation, the organic thin film may be, e.g., an SOH.

In drawing (a), only patterns having identical sizes are illustrated. When patterns having different sizes are disposed together and the dry etching is performed on the organic thin film disposed on the patterns, the etched thickness of the organic thin film disposed on the patterns may be changed by a loading effect. Further, gradients of side surfaces of each protruding portion may be changed in each of the patterns.

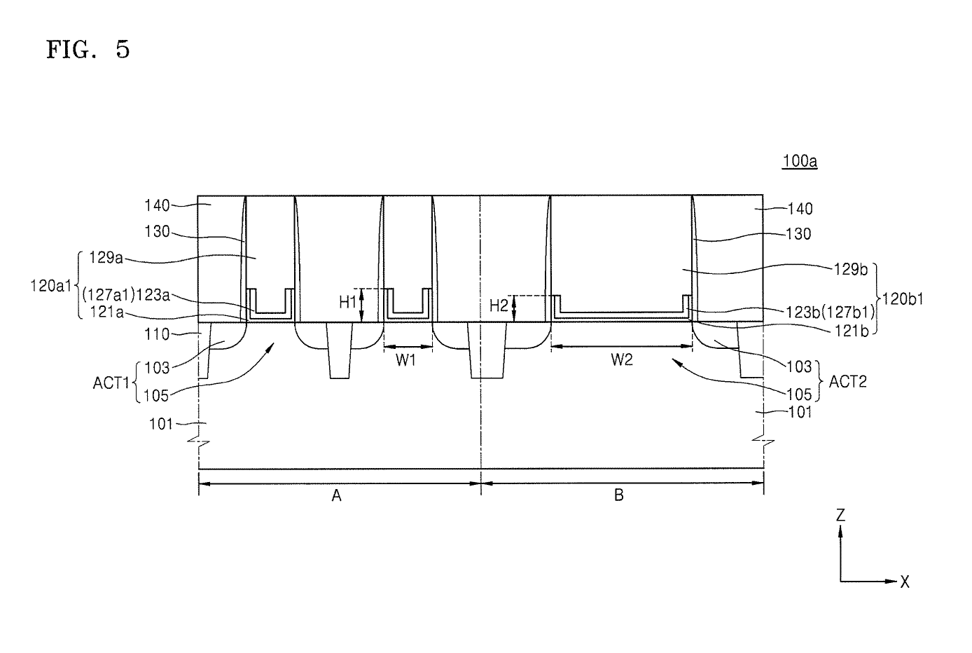

FIGS. 5 to 8 illustrates cross-sectional views of semiconductor devices according to embodiments corresponding to FIG. 2A. Content already described in FIGS. 1 to 3B will be briefly described or omitted.

Referring to FIG. 5, a semiconductor device 100a according to an embodiment may have lower metal layers 127a1 and 127b1 having structures different from those of the semiconductor device 100 in FIG. 2A. For example, in the semiconductor device 100a in the present embodiment, each of the lower metal layers 127a1 and 127b1 may include a single metal layer. For example, a first lower metal layer 127a1 may include a first metal layer 123a, and a second lower metal layer 127b1 may include a first metal layer 123b. The first metal layers 123a and 123b may include, e.g., TaN.

As illustrated in the semiconductor device 100 of FIG. 2A, a cross section of each of the lower metal layers 127a1 and 127b1 may have a U-shaped structure. For example, the cross section of the first lower metal layer 127a1 may have the U-shaped structure, and heights of protruding portions at both side surfaces thereof may have a first height H1 from an upper surface of a substrate 101. Further, the cross section of the second lower metal layer 127b1 may also have the U-shaped structure, and heights of protruding portions at both side surfaces thereof may have a second height H2 from the upper surface of the substrate 101. The second height H2 may be the same as or smaller than the first height H1.

A first gate length W1 and a second gate length W2 may also be different in the semiconductor device 100a in the present embodiment, and a threshold voltage of a transistor formed with a first gate structure 120a1 and a threshold voltage of a transistor formed with a second gate structure 120b1 may be different. Further, each of the lower metal layers 127a1 and 127b1 may be formed with a single metal layer, and the threshold voltage of the transistor formed with the first gate structure 120a1 may be different from a threshold voltage of a transistor formed with the first gate structure 120a of FIG. 2A, and the threshold voltage of the transistor formed with the second gate structure 120b1 may be different from a threshold voltage of a transistor formed with the second gate structure 120b of FIG. 2A.

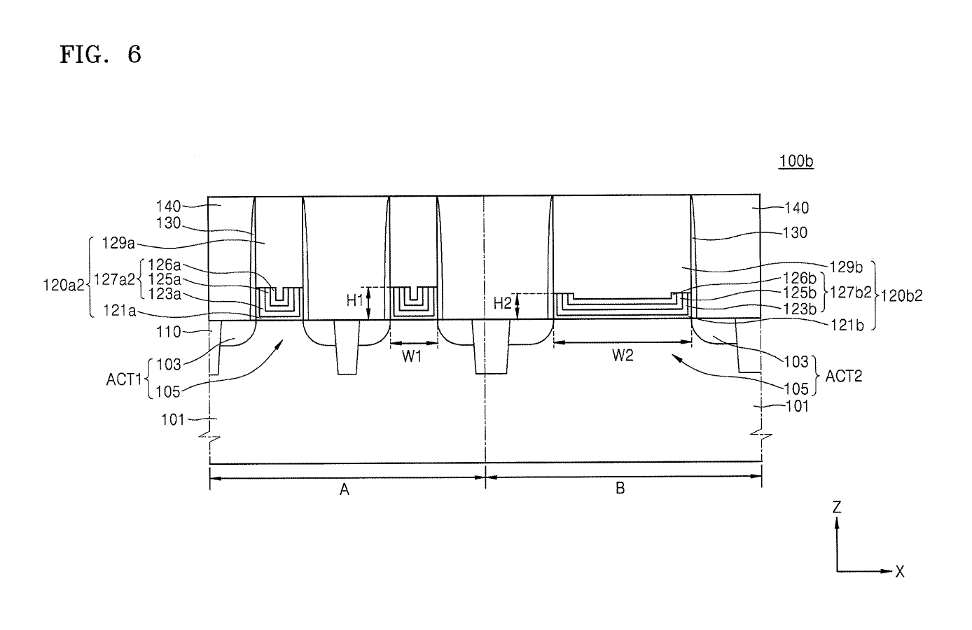

Referring to FIG. 6, a semiconductor device 100b according to an embodiment may have lower metal layers 127a2 and 127b2 having structures different from those of the semiconductor device 100 in FIG. 2A. For example, in the semiconductor device 100b in the present embodiment, each of the lower metal layers 127a2 and 127b2 may include three metal layers. For example, a first lower metal layer 127a2 may include a first metal layer 123a, a second metal layer 125a, and a third metal layer 126a, and a second lower metal layer 127b2 may include a first metal layer 123b, a second metal layer 125b, and a third metal layer 126b. The first metal layers 123a and 123b may include, e.g., TiN. The second metal layers 125a and 125b may include, e.g., TaN. The third metal layers 126a and 126b may include, e.g., TiN.

A cross section of each of the lower metal layers 127a2 and 127b2 may have a U-shaped structure. Heights of protruding portions at both side surfaces of the first lower metal layer 127a2 may have a first height H1 from an upper surface of a substrate 101. Heights of protruding portions at both side surfaces of the second lower metal layer 127b2 may have a second height H2 from the upper surface of the substrate 101. The second height H2 may be the same as or smaller than the first height H1.

A first gate length W1 and a second gate length W2 may be different in the semiconductor device 100b in the present embodiment, and a threshold voltage of a transistor formed with a first gate structure 120a2 and a threshold voltage of a transistor formed with a second gate structure 120b2 may be different. Further, each of the lower metal layers 127a2 and 127b2 may be formed as three metal layers, and the threshold voltage of the transistor formed with the first gate structure 120a2 may be different from threshold voltages of transistors formed with the first gate structures 120a and 120a1 of FIGS. 2A and 5, and the threshold voltage of the transistor formed with the second gate structure 120b2 may be different from threshold voltages of transistors formed with the second gate structures 120b and 120b1 of FIGS. 2A and 5.

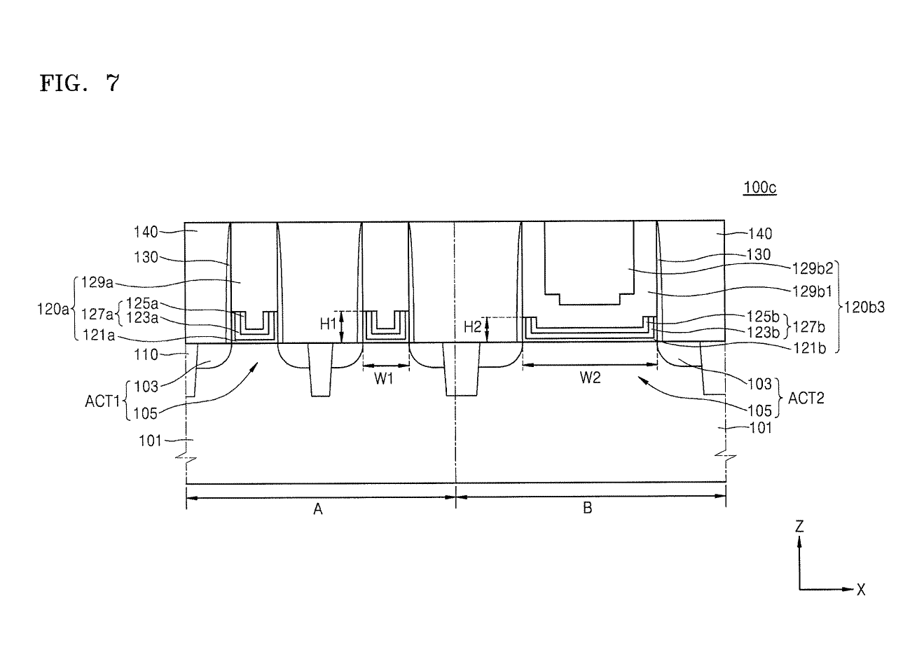

Referring to FIG. 7, a semiconductor device 100c according to an embodiment may have a second gate structure 120b3 having a structure different from that of the semiconductor device 100 in FIG. 2A. For example, in the semiconductor device 100c in the present embodiment, the second gate structure 120b3 may include a second high-k dielectric layer 121b, a second lower metal layer 127b, a second upper metal layer 129b1, and a gap fill metal layer 129b2. The second high-k dielectric layer 121b and the second lower metal layer 127b may be the same as those described in FIGS. 1 to 2B.

The second upper metal layer 129b1 may have a different shape from the second upper metal layer 129b of FIG. 2A. For example, the second upper metal layer 129b1 may only partially fill between spacers 130 on the second high-k dielectric layer 121b and the second lower metal layer 127b. For example, the second upper metal layer 129b1 may have a structure that covers upper surfaces of the second high-k dielectric layer 121b and the second lower metal layer 127b and side surfaces of the spacers 130 to a predetermined thickness. When the second gate length W2 is large, the second upper metal layer 129b1 may be formed to have a structure that only partially fills between the spacers 130 and covers the upper surfaces of the lower layers and the side surfaces of the spacers 130 in this manner. In addition, material, function or the like of the second upper metal layer 129b1 may be the same as those described in FIGS. 1 to 2B.

The gap fill metal layer 129b2 may be a metal layer that fills a gap between the spacers 130 on the second upper metal layer 129b1. The gap fill metal layer 129b2 may include, e.g., tungsten (W). The gap fill metal layer 129b2 may be formed of various suitable metals to fill the gap. In an implementation, the gap fill metal layer 129b2 may include, e.g., a metal nitride such as TiN, TaN, or the like, Al, a metal carbide, a metal silicide, a metal aluminum carbide, a metal aluminum nitride, a metal silicon nitride, or the like.

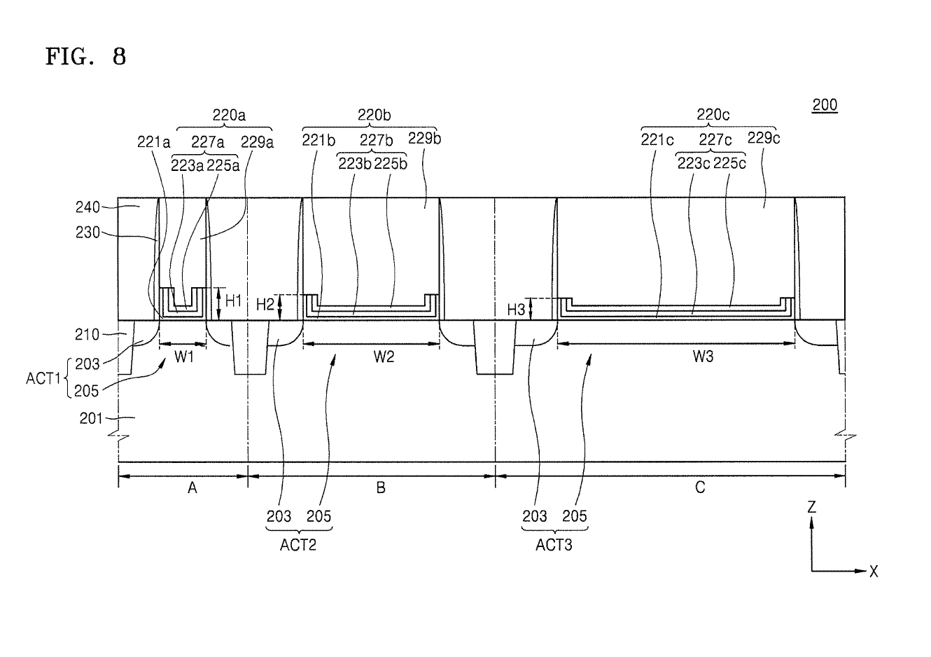

Referring to FIG. 8, a semiconductor device 200 according to an embodiment may include a substrate 201 and gate structures 220a, 220b, and 220c. The substrate 201 may include a first region A, a second region B, and a third region C. A material and the like of the substrate 201 are the same as those described in FIGS. 1 to 2B.

Active regions ACT1, ACT2, and ACT3 may be defined by a device isolation layer 210 in an upper region of the substrate 201. The active regions ACT1, ACT2, and ACT3 may include a first active region ACT1 in the first region A, a second active region ACT2 in the second region B, and a third active region ACT3 in the third region C. Each of the active regions ACT1, ACT2, and ACT3 may include source/drain regions 203 and a channel region 205.

The gate structures 220a, 220b, and 220c may be disposed on the substrate 201 respectively across the corresponding active regions ACT1, ACT2, and ACT3. For example, the gate structures 220a, 220b, and 220c may include a first gate structure 220a in the first region A, a second gate structure 220b in the second region B, and a third gate structure 220c in the third region C.

Spacers 230 may be formed at both side surfaces of each of the gate structures 220a, 220b, and 220c. Further, the spacers 230 may be surrounded by an interlayer insulating layer 240. Materials or shapes of the spacers 230 and the interlayer insulating layer 240 are the same as those described in FIGS. 1 to 2B.

The first gate structure 220a may have a first gate length W1, the second gate structure 220b may have a second gate length W2, and the third gate structure 220c may have a third gate length W3. As illustrated in the drawing, the first gate length W1 may have the smallest size, the third gate length W3 may have the greatest size, and the second gate length W2 may have an intermediate size.

The gate structures 220a, 220b, and 220c may respectively include high-k dielectric layers 221a, 221b, and 221c, lower metal layers 227a, 227b, and 227c, and upper metal layers 229a, 229b, and 229c. A cross section of each of the lower metal layers 227a, 227b, and 227c may be formed to have a U-shaped structure. For example, heights of protruding portions at both side surfaces of a first lower metal layer 227a may have a first height H1 from an upper surface of the substrate 201, heights of protruding portions at both side surfaces of a second lower metal layer 227b may have a second height H2 from the upper surface of the substrate 201, and heights of protruding portions at both side surfaces of a third lower metal layer 227c may have a third height H3 from the upper surface of the substrate 201. In an implementation, the first height H1, the second height H2, and the third height H3 may be the same. In an implementation, at least two of the first height H1, the second height H2, and the third height H3 may be the same. In an implementation, all of the first height H1, the second height H2, and the third height H3 may be different. When all of the first height H1, the second height H2, and the third height H3 are different, the first height H1 may be the greatest, and the third height H3 may be the smallest.

In addition, materials, functions, or the like of the high-k dielectric layers 221a, 221b, and 221c, the lower metal layers 227a, 227b, and 227c, and the upper metal layers 229a, 229b, and 229c are the same as those described in FIGS. 1 to 2B.

In the semiconductor device 200 of the present embodiment, as the lower metal layers 227a, 227b, and 227c having the buried U-shaped structure are applied to the gate structures 220a, 220b, and 220c, respectively, three transistors having three different threshold voltages in which each threshold voltage is uniform may be implemented. For example, as the three gate structures 220a, 220b, and 220c having different gate lengths include the lower metal layers 227a, 227b, and 227c having the buried U-shaped structure, respectively, the transistors formed with the gate structures 220a, 220b, and 220c may have different threshold voltages. Therefore, in the semiconductor device 200 in the present embodiment, due to the lower metal layers 227a, 227b, and 227c having the buried U-shaped structure, transistors having three different threshold voltages in which each threshold voltage is uniform and a semiconductor device including such transistors, for example, a logic device, may be easily implemented.

In the semiconductor device 200 in the present embodiment, due to the three gate structures 220a, 220b, and 220c, transistors having three different threshold voltages may be implemented. In an implementation, as each of at least four gate structures having different gate lengths includes lower metal layers having a buried U-shaped structure, transistors having at least four different threshold voltages may be implemented.

Up to now, the semiconductor devices 100, 100a, 100b, 100c, and 200 including the gate structures having various structures were described. In an implementation, when any gate structure is implemented so as to include a lower metal layer having a buried U-shaped structure while having various gate lengths, that gate structure would fall within the scope of the inventive concept regardless of its detailed structure, materials, or the like.

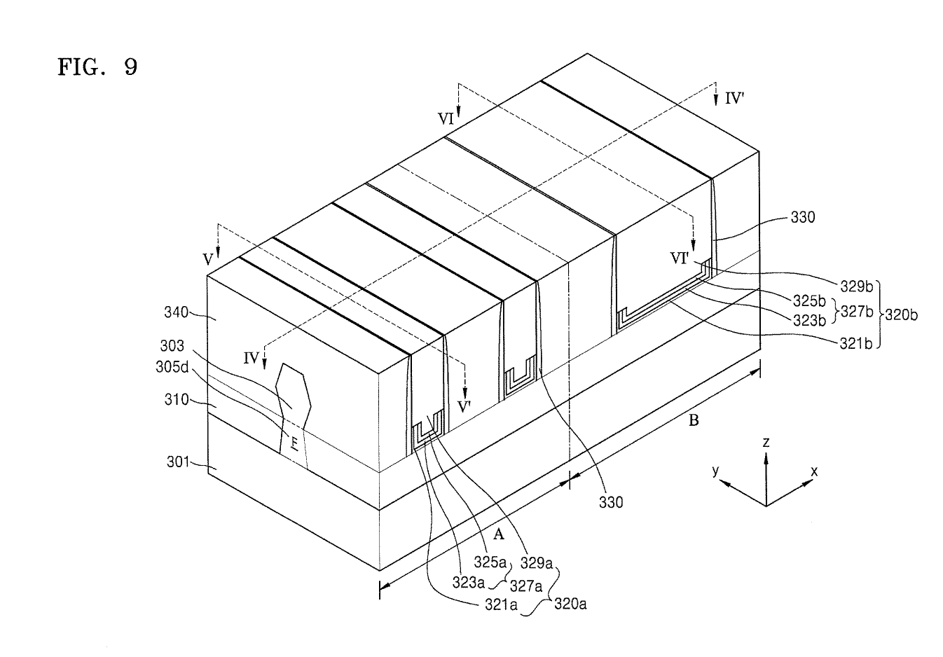

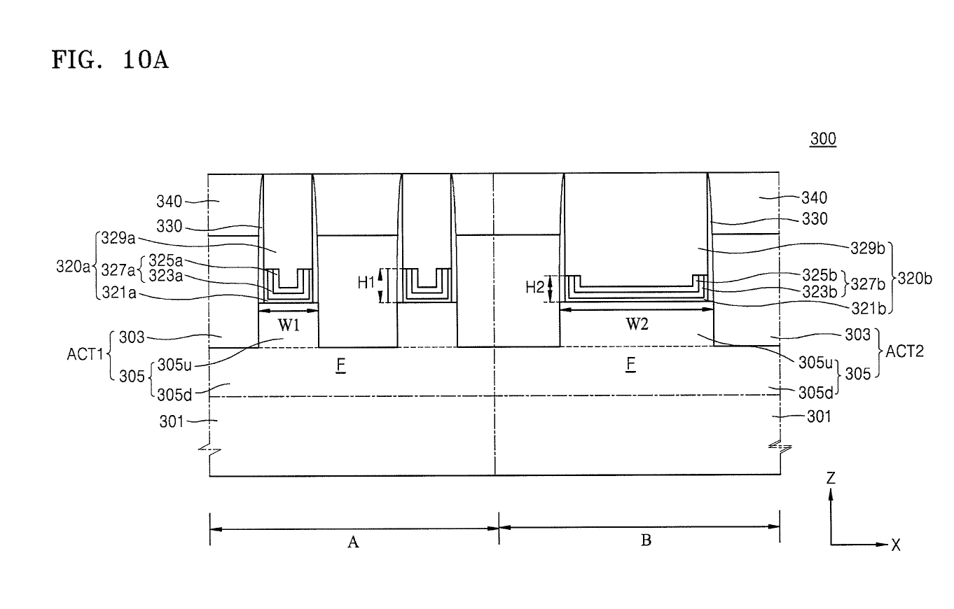

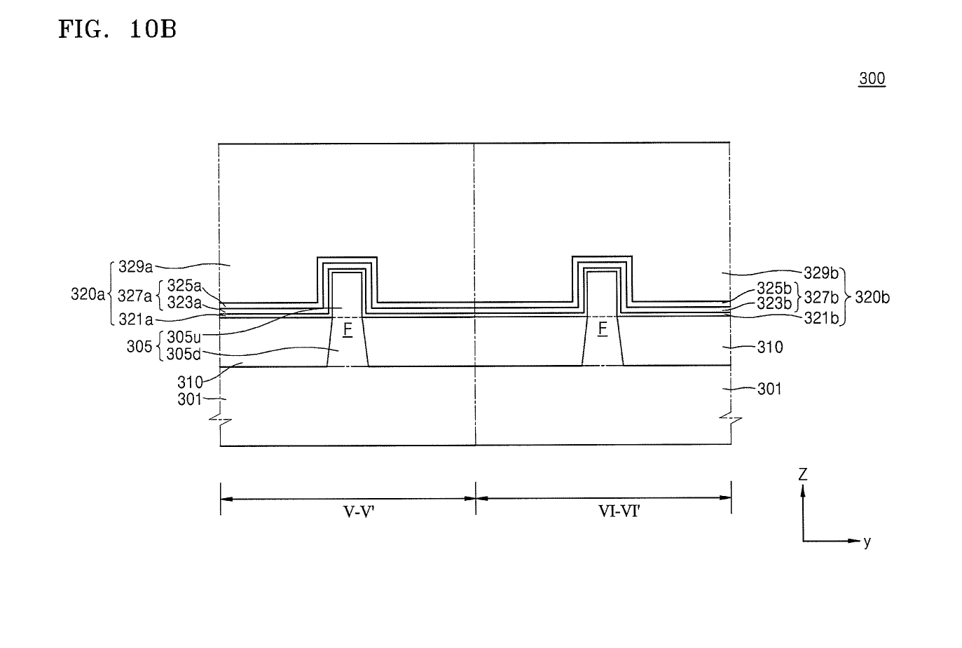

FIG. 9 illustrates a perspective view of a semiconductor device, in which a multi-threshold voltage is implemented, according to an embodiment, FIG. 10A illustrates a cross-sectional view of the semiconductor device of FIG. 9 taken along line IV-IV′, and FIG. 10B illustrates a cross-sectional view of the semiconductor device taken along lines V-V′ and VI-VI′. Content already described in FIGS. 1 to 8 maybe be briefly described or omitted.

Referring to FIGS. 9 to 10B, a semiconductor device 300 according to the present embodiment may include a substrate 301, active regions ACT1 and ACT2 (hereinafter, referred to as fin active regions) having a fin F structure, and gate structures 320a and 320b. For example, the semiconductor device 300 in the present embodiment may include the substrate 301, the fin active regions ACT1 and ACT2, a device isolation layer 310, the gate structures 320a and 320b, and an interlayer insulating layer 340.

The substrate 301 may include a first region A and a second region B. The substrate 301 may correspond to the substrate 101 of the semiconductor device 100 of FIG. 1. Accordingly, detailed description of the substrate 301 may be omitted.

The fin active regions ACT1 and ACT2 may be formed to have a structure which protrudes from the substrate 301 and extends in a first direction (an X direction). The fin active regions ACT1 and ACT2 may include a first fin active region ACT1 in the first region A and a second fin active region ACT2 in the second region B. Each of the first fin active region ACT1 and the second fin active region ACT2 may be formed on the substrate 301 along a second direction (a Y direction) in multiple regions. A plurality of first fin active regions ACT1 and a plurality of second fin active regions ACT2 may be electrically insulated from each other through the device isolation layer and the like.

In an implementation, the fin active regions ACT1 and ACT2 may be disposed to by perpendicularly crossing each of the corresponding gate structures 320a and 320b as illustrated in FIG. 9. In an implementation, the fin active regions ACT1 and ACT2 may respectively cross the corresponding gate structures 320a and 320b at an angle which is not perpendicular thereto. In an implementation, a single first gate structure 320a crosses a single first fin active region ACT1 and a single second gate structure 320b crosses a single second fin active region ACT2. In an implementation, a plurality of first gate structures 320a may cross a single first fin active region ACT1, and a plurality of second gate structures 320b may cross a single second fin active region ACT2. In an implementation, a single first gate structure 320a may also cross a plurality of first fin active regions ACT1, and a single second gate structure 320b may also cross a plurality of second fin active regions ACT2. In an implementation, the first fin active region ACT1 in the first region A and the second fin active region ACT2 in the second region B extend in the same first direction (the X direction), but may also extend in different directions. In an implementation, the first gate structure 320a in the first region A and the second gate structure 320b in the second region B may extend in different directions.

Each of the first fin active region ACT1 and the second fin active region ACT2 may include a fin 305 and source/drain regions 303. The fin 305 may include a lower fin portion 305d (of which both side surfaces are surrounded by the device isolation layer 310) and an upper fin portion 305u (protruding from an upper surface of the device isolation layer 310). The upper fin portion 305u may be present under the gate structures 320a and 320b, and may constitute a channel region. The source/drain regions 303, which are both side surfaces of each of the gate structures 320a and 320b, may be formed on an upper portion of the lower fin portion 305d.

The fin 305 may be formed based on the substrate 301, and the source/drain regions 303 may be formed with an epitaxial layer grown on the lower fin portion 305d. In an implementation, the upper fin portion 305u may be present as the both side surfaces of the gate structures 320a and 320b, and the upper fin portion 305u may also constitute a source/drain region. For example, the source/drain region may not be formed through a separate epitaxial layer growth, but may also be formed as the upper fin portion 305u of the fin 305 the same as the channel region.

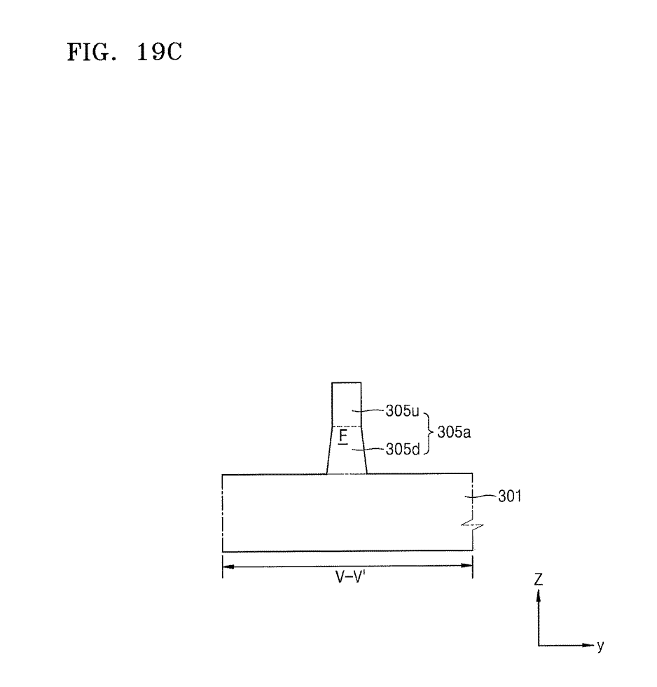

As described above, when the fin 305 is formed based on the substrate 301, the fin 305 may include silicon or germanium, which is a semiconductor element. In an implementation, the fin 305 may include a compound semiconductor such as a IV-IV group compound semiconductor or a III-V group compound semiconductor. For example, the fin 305 may include a binary compound or a ternary compound containing at least two selected from a group consisting of carbon (C), silicon (Si), germanium (Ge), and tin (Sn), or a compound in which the binary compound or the ternary compound is doped with a IV group element, as the IV-IV group compound semiconductor. In an implementation, the fin 305 may include, e.g., a binary compound, a ternary compound, and a quaternary compound, which are formed by combining at least one selected from a group consisting of aluminum (Al), gallium (Ga), and indium (In) which are III group elements with one selected from phosphorus (P), arsenic (As), and anti-ammonium (Sb) which are V group elements, as the III-V group compound semiconductor. A structure and a method of forming the fin 305 will be described in more detail in descriptions of FIGS. 19A to 27C.

Meanwhile, when the source/drain regions 303 are formed with an epitaxial layer grown on the lower fin portion 305d or are formed with the fin 305, the source/drain regions 303 may be formed at both sides of each of the gate structures 320a and 320b and on the lower fin portion 305d, and may include a compressive stress material or a tensile stress material according to a required channel type of the transistor. For example, when a PMOS transistor is formed, the source/drain regions 303 at the both side surfaces of each of the gate structures 320a and 320b may include a compressive stress material. For example, when the lower fin portion 305d is formed of silicon, the source/drain regions 303 may be formed of a material having a lattice constant greater than that of silicon serving as the compressive stress material, for example, silicon germanium (SiGe). In an implementation, when an NMOS transistor is formed, the source/drain regions 303 at the both side surfaces of each of the gate structures 320a and 320b may include a tensile stress material. For example, when the lower fin portion 305d is formed of silicon, the source/drain regions 303 may be formed of silicon or a material having a lattice constant greater than that of silicon serving as the tensile stress material, e.g., silicon carbide (SiC).

In the semiconductor device 300 in the present embodiment, the source/drain regions 303 may have various shapes. For example, in a cross section perpendicular to the first direction (the X direction), the source/drain regions 303 may have various shapes such as a diamond shape, a circular shape, an elliptical shape, a polygonal shape, or the like. FIG. 9 illustrates the source/drain regions 303 having a hexagonal diamond shape as an example.

The device isolation layer 310 may be formed on the substrate 301 to surround both side surfaces of the lower fin portion 305d of the fin 305. The device isolation layer 310 may correspond to the device isolation layer 110 of the semiconductor device 100 in FIG. 1, and may function to electrically separate fins disposed along the second direction (the Y direction) from each other. Such a device isolation layer 310 may include, e.g., at least one of a silicon oxide film, a silicon nitride film, a silicon oxynitride film, and a combination thereof. The upper fin portion 305u of the fin 305 may have a structure that is not surrounded by the device isolation layer 310 and that protrudes from the device isolation layer 310. In an implementation, as illustrated in FIGS. 10A and 10B, the upper fin portion 305u of the fin 305 may be disposed only under the gate structures 320a and 320b, and may constitute a channel region.

The gate structures 320a and 320b may extend in the second direction (the Y direction) across the corresponding fin 305 on the device isolation layer 310. For example, the gate structures 320a and 320b may include a first gate structure 320a disposed in the first region A and a second gate structure 320b disposed in the second region B. As described above, each of the first gate structure 320a and the second gate structure 320b may be disposed in multiple structures for a single fin 305. A plurality of first gate structures 320a or a plurality of second gate structures 320b may be disposed along the first direction (the X direction) to be spaced apart from each other. Each of the first gate structure 320a and the second gate structure 320b may have a structure which surrounds an upper surface and side surfaces of the upper fin portion 305u of the fin 305.

The fin 305 may also be disposed on each of the first gate structure 320a and the second gate structure 320b in multiple structures. A plurality of fins 305 may be disposed along the second direction (the Y direction) to be spaced apart from each other.

The first gate structure 320a in the first region A may have a first gate length W1, and the second gate structure 320b in the second region B may have a second gate length W2. The first gate length W1 may be smaller than the second gate length W2. In an implementation, the second gate length W2 may be at least two times the first gate length W1. In an implementation, the second gate length W2 may be at least five times the first gate length W1.

In an implementation, two first gate structures 320a may be disposed in the first region A, and a single second gate structure 320b may be disposed in the second region B. In an implementation, a single first gate structure 320a or three or more first gate structures 320a may be disposed in the first region A. In an implementation, at least two second gate structures 320b may be disposed in the second region B. In an implementation, the first gate structure 320a may be disposed in the first region A with a dense density, and the second gate structure 320b may be disposed in the second region B with a sparse density.

The gate structures 320a and 320b may respectively include high-k dielectric layers 321a and 321b, lower metal layers 327a and 327b, and upper metal layers 329a and 329b. In an implementation, a cross section of each of the lower metal layers 327a and 327b may have a U-shaped structure. For example, each of the lower metal layers 327a and 327b may have a U-shaped structure with respect to a cross section perpendicular to the second direction (the Y direction). As illustrated in FIG. 10B, with respect to the cross section perpendicular to the first direction (the X direction), each of the lower metal layers 327a and 327b may have a structure which extends in the second direction while covering the side surfaces and the upper surface of the upper fin portion 305u.

In addition, materials, functions, and the like of the layers constituting each of the gate structures 320a and 320b are the same as those described in FIGS. 1 to 2B. However, in the semiconductor device 300 in the present embodiment, as the gate structures 320a and 320b are formed to have a structure which covers the fin 305, a structure of the cross section of FIG. 10B may be different from that of FIG. 2B. Further, as illustrated in FIG. 10A, as the source/drain regions 303 are formed on the lower fin portion 305d, a structure of the source/drain regions 303 at both side surfaces of each of the gate structures 320a and 320b may also be different from that of the source/drain region 103 of FIG. 2A.

The interlayer insulating layer 340 may be formed on the device isolation layer 310 to cover the source/drain regions 303. For example, the interlayer insulating layer 340 may have a structure that surrounds an upper surface and side surfaces of each of the source/drain regions 303. Such an interlayer insulating layer 340 may correspond to the interlayer insulating layer 140 of the semiconductor device 100 in FIGS. 1 to 2B. Therefore, a material, a function, and the like of the interlayer insulating layer 340 are the same as those described in FIGS. 1 to 2B.

Spacers 330 may be formed between the interlayer insulating layer 340 and the gate structures 320a and 320b. The spacers 330 may have a structure that surrounds both side surfaces of each of the gate structures 320a and 320b and that extend in the second direction (the Y direction). In an implementation, the spacers 330 may have a structure that crosses the fin 305 similarly to the gate structures 320a and 320b and surrounds the upper surface and the side surfaces of the upper fin portion 305u. Such spacers 330 may correspond to the spacers 130 of the semiconductor device 100 in FIGS. 1 to 2B. Therefore, a material and the like of the spacer 130 are the same as those described in FIGS. 1 to 2B.

In the semiconductor device 300 in the present embodiment, as the gate structures 320a and 320b having different gate lengths respectively include the lower metal layers 327a and 327b having the buried U-shaped structure, a transistor having different threshold voltages in which each threshold voltage is uniform may be implemented. In an implementation, due to the lower metal layers 327a and 327b having the buried U-shaped structure, a semiconductor device including transistors having various threshold voltages, e.g., a logic device, may be easily implemented.

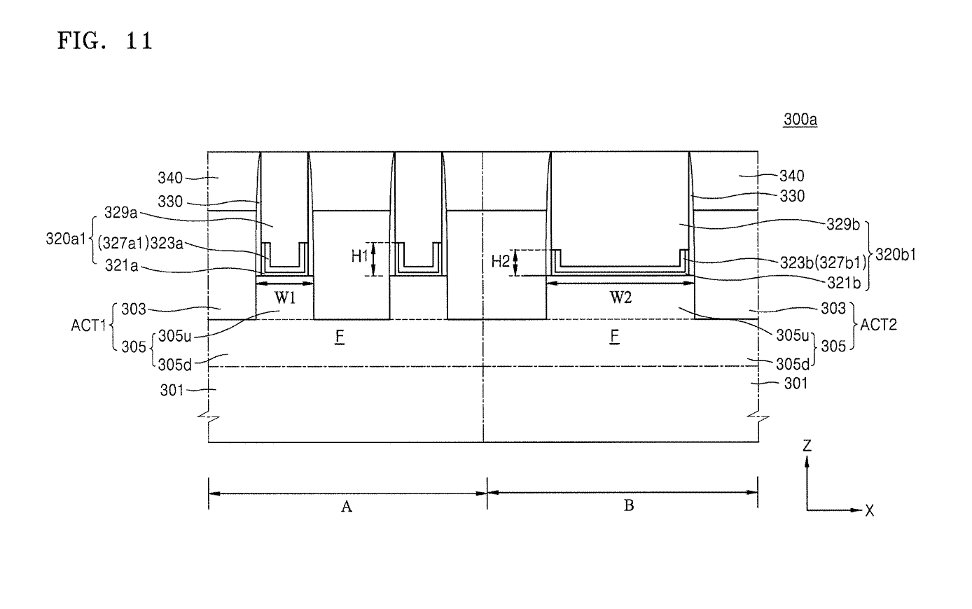

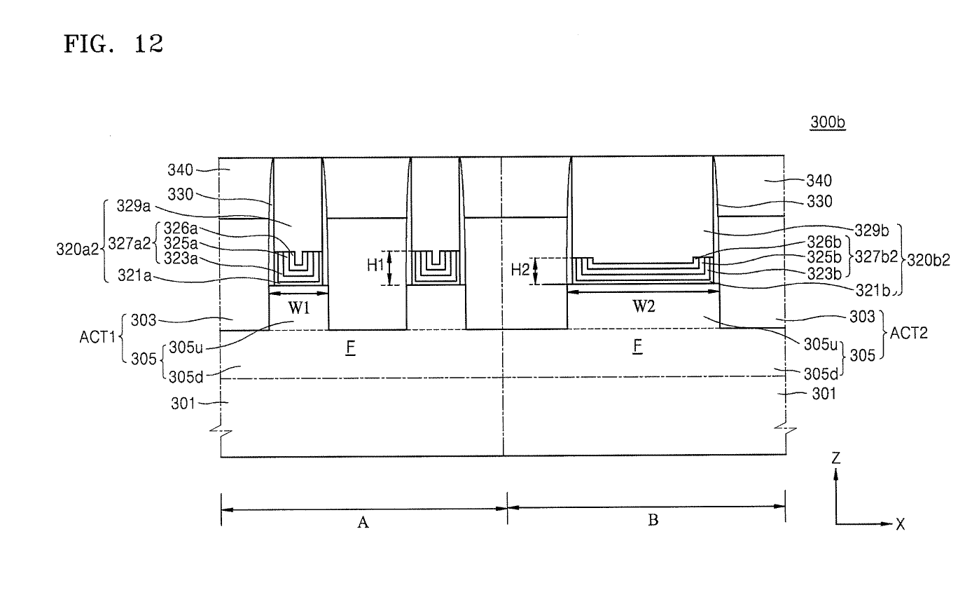

FIGS. 11 to 14, illustrate cross-sectional views of semiconductor devices according to embodiments corresponding to FIG. 10A. Content already described in FIGS. 1 to 10B may be briefly described or omitted.

Referring to FIG. 11, a semiconductor device 300a of the present embodiment may have lower metal layers 327a1 and 327b1 having structures different from those of the semiconductor device 300 in FIG. 10A. For example, in the semiconductor device 300a in the present embodiment, each of the lower metal layers 327a1 and 327b1 may include a single metal layer. For example, the first lower metal layer 327a1 may include a first metal layer 323a and the second lower metal layer 327b1 may include a first metal layer 323b. In an implementation, the first metal layers 323a and 323b may include, e.g., TaN.

A cross section of each of the lower metal layers 327a1 and 327b1 may also have a U-shaped structure. For example, heights of protruding portions at both side surfaces of the first lower metal layer 327a1 may have a first height H1 from a fin 305, e.g., an upper surface of an upper fin portion 305u. Further, heights of protruding portions at both side surfaces of the second lower metal layer 327b1 may have a second height H2 from the upper surface of the upper fin portion 305u. The second height H2 may be the same as or smaller than the first height H1. Meanwhile, when a cross section perpendicular to a second direction (a Y direction) is a portion without the fin 305, each of the first height H1 and the second height H2 may be a height from an upper surface of the device isolation layer 310.

A first gate length W1 and a second gate length W2 may also be different in the semiconductor device 300a in the present embodiment, and a threshold voltage of a transistor formed with the first gate structure 320a1 and a threshold voltage of a transistor formed with the second gate structure 320b1 may be different. In an implementation, each of the lower metal layers 327a1 and 327b1 may be formed with a single metal layer, and the threshold voltage of the transistor formed with the first gate structure 320a1 may be different from a threshold voltage of a transistor formed with the first gate structure 320a of FIG. 10A, and the threshold voltage of the transistor formed with the second gate structure 320b1 may be different from a threshold voltage of a transistor formed with the second gate structure 320b of FIG. 10A.

Referring to FIG. 12, a semiconductor device 300b of the present embodiment may have lower metal layers 327a2 and 327b2 having structures different from those of the semiconductor device 300 in FIG. 10A. For example, in the semiconductor device 300b in the present embodiment, each of the lower metal layers 327a2 and 327b2 may include three metal layers. For example, the first lower metal layer 327a2 may include a first metal layer 323a, a second metal layer 325a, and a third metal layer 326a, and the second lower metal layer 327b2 may include a first metal layer 323b, a second metal layer 325b, and a third metal layer 326b. In an implementation, the first metal layers 323a and 323b may include, e.g., TiN. In an implementation, the second metal layers 325a and 325b may include TaN. The third metal layers 326a and 326b may include, e.g., TiN.

A cross section of each of the lower metal layers 327a2 and 327b2 may have a U-shaped structure. Heights of protruding portions at both side surfaces of the first lower metal layer 327a2 may have a first height H1 from an upper surface of an upper fin portion 305u. Heights of protruding portions at both side surfaces of the second lower metal layer 327b2 may have a second height H2 from the upper surface of the upper fin portion 305u. In an implementation, the second height H2 may be the same as or smaller than the first height H1.

A first gate length W1 and a second gate length W2 may be different in the semiconductor device 300b in the present embodiment, and a threshold voltage of a transistor formed with the first gate structure 320a2 and a threshold voltage of a transistor formed with the second gate structure 320b2 may be different. Each of the lower metal layers 327a2 and 327b2 may be formed with three metal layers, and the threshold voltage of the transistor formed with the first gate structure 320a2 may be different from threshold voltages of transistors formed with the first gate structures 320a and 320a1 of FIGS. 10A and 11, and the threshold voltage of the transistor formed with the second gate structure 320b2 may be different from threshold voltages of transistors formed with the second gate structures 320b and 320b1 of FIGS. 10A and 11.

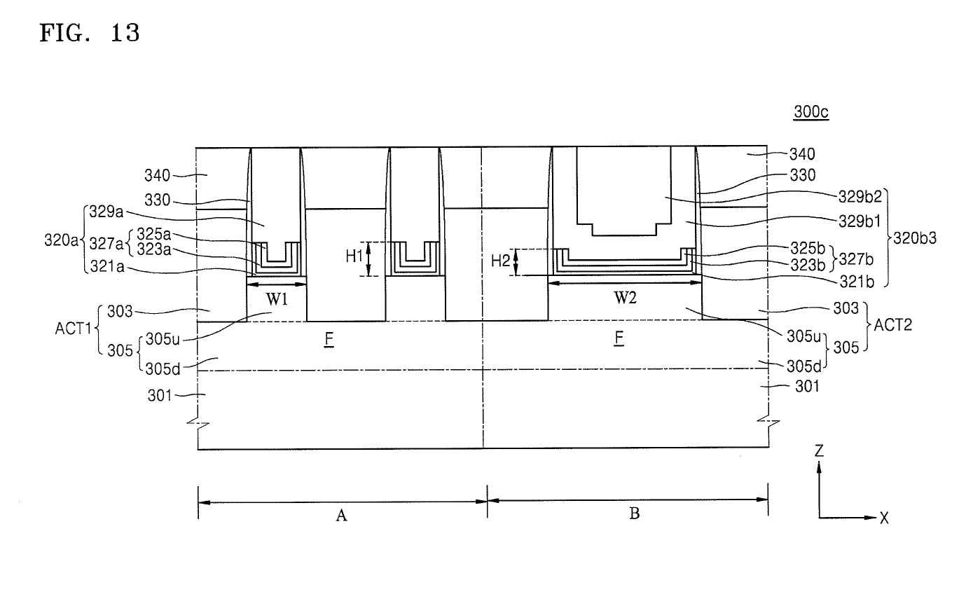

Referring to FIG. 13, a semiconductor device 300c of the present embodiment may have a second gate structure 320b3 having a structure different from the semiconductor device 300 in FIG. 10A. For example, in the semiconductor device 300c in the present embodiment, the second gate structure 320b3 may include a second high-k dielectric layer 321b, a second lower metal layer 327b, a second upper metal layer 329b1, and a gap fill metal layer 329b2.

The second upper metal layer 329b1 may have a different shape from that of the second upper metal layer 329b in FIG. 10A. For example, the second upper metal layer 329b1 may only partially fill between spacers 330 on the second high-k dielectric layer 321b and the second lower metal layer 327b. For example, the second upper metal layer 329b1 may have a structure that covers upper surfaces of the second high-k dielectric layer 321b and the second lower metal layer 327b and side surfaces of each of the spacers 330 to a predetermined thickness. When a second gate length W2 is large, the second upper metal layer 329b1 may have a structure that only partially fills between the spacers 330 and covers the upper surfaces of the lower layers and the side surfaces of the spacers 330 in this manner.

The gap fill metal layer 329b2 may be a metal layer that fills a remaining gap between the spacers 330 on the second upper metal layer 329b1. In an implementation, the gap fill metal layer 329b2 may include, e.g., tungsten (W). In an implementation, the gap fill metal layer 329b2 may be formed of various suitable metals to fill the gap.

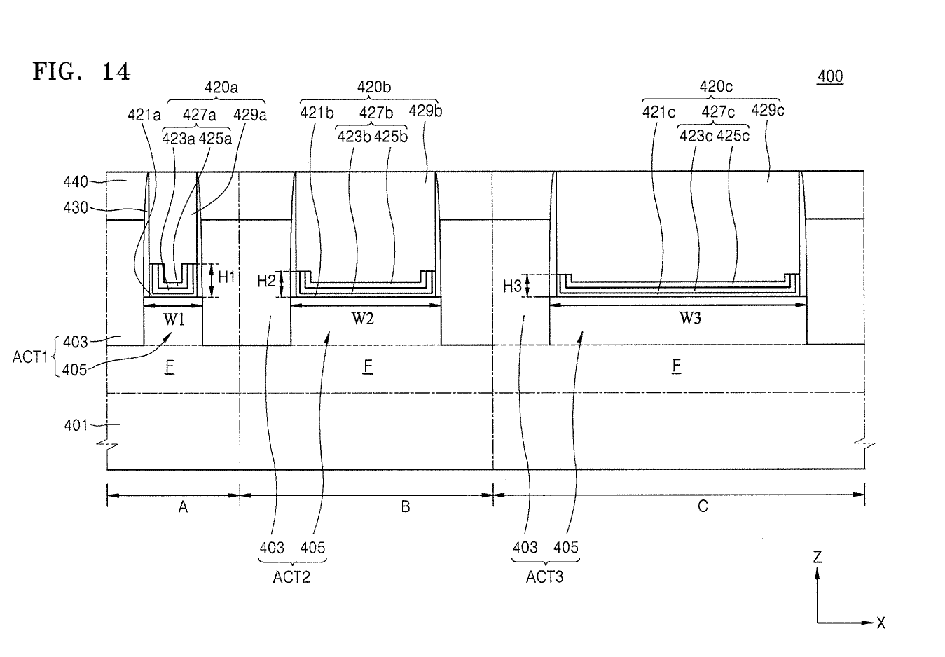

Referring to FIG. 14, a semiconductor device 400 according to the present embodiment may include a substrate 401 and gate structures 420a, 420b, and 420c. The substrate 401 may include a first region A, a second region B, and a third region C. A material and the like of the substrate 401 may be the same as those described in FIGS. 1 to 2B.

Active regions ACT1, ACT2, and ACT3 may be defined by a device isolation layer in an upper region of the substrate 401. The active regions ACT1, ACT2, and ACT3 may include a first active region ACT1 in the first region A, a second active region ACT2 in the second region B, and a third active region ACT3 in the third region C. Each of the active regions ACT1, ACT2, and ACT3 may include source/drain regions 403 and a channel region.

The gate structures 420a, 420b, and 420c may be disposed on the substrate 401 across the corresponding active regions ACT1, ACT2, and ACT3, respectively. For example, the gate structures 420a, 420b, and 420c may include a first gate structure 420a in the first region A, a second gate structure 420b in the second region B, and a third gate structure 420c in the third region C.

Spacers 430 may be formed at both side surfaces of each of the gate structures 420a, 420b, and 420c. Further, the spacers 430 may be surrounded by an interlayer insulating layer 440. Materials or shapes of the spacers 430 and the interlayer insulating layer 440 are the same as those described in FIGS. 1 to 2B.

The first gate structure 420a may have a first gate length W1, the second gate structure 420b may have a second gate length W2, and the third gate structure 420c may have a third gate length W3. As illustrated in the drawing, the first gate length W1 may have the smallest size, the third gate length W3 may have the greatest size, and the second gate length W2 may have an intermediate size.

The gate structures 420a, 420b, and 420c may respectively include high-k dielectric layers 421a, 421b, and 421c, lower metal layers 427a, 427b, and 427c, and upper metal layers 429a, 429b, and 429c. A cross section of each of the lower metal layers 427a, 427b, and 427c may be formed to have a U-shaped structure. For example, heights of protruding portions at both side surfaces of a first lower metal layer 427a may have a first height H1 from an upper surface of an upper fin portion 405, heights of protruding portions at both side surfaces of a second lower metal layer 427b may have a second height H2 from the upper surface of the upper fin portion 405, and heights of protruding portions at both side surfaces of a third lower metal layer 427c may have a third height H3 from the upper surface of the upper fin portion 405. In an implementation, the first height H1, the second height H2, and the third height H3 may be the same. In an implementation, at least two of the first height H1, the second height H2, and the third height H3 may be the same. In an implementation, all of the first height H1, the second height H2, and the third height H3 may be different. When all of the first height H1, the second height H2, and the third height H3 are different, the first height H1 may be the greatest, and the third height H3 may be the smallest.

In addition, materials, functions, and the like of the high-k dielectric layers 421a, 421b, and 421c, the lower metal layers 427a, 427b, and 427c and the upper metal layers 429a, 429b, and 429c are the same as those described in FIGS. 1 to 2B.

In the semiconductor device 400 of the present embodiment, as the lower metal layers 427a, 427b, and 427c having the buried U-shaped structure are respectively applied to the gate structures 420a, 420b, and 420c, three transistors having three different threshold voltages in which each threshold voltage is uniform may be implemented. For example, the three gate structures 420a, 420b, and 420c having different gate lengths respectively include the lower metal layers 427a, 427b, and 427c having a buried U-shaped structure, and the transistors formed with the gate structures 420a, 420b, and 420c may have different threshold voltages. Therefore, in the semiconductor device 400 in the present embodiment, due to the lower metal layers 427a, 427b, and 427c having the buried U-shaped structure, transistors having three different threshold voltages in which each threshold voltage is uniform and a semiconductor device including such transistors, for example, a logic device, may be easily implemented.

In the semiconductor device 400 in the present embodiment, due to the three gate structures 420a, 420b, and 420c, transistors having three different threshold voltages may be implemented. In an implementation, at least four gate structures having different gate lengths may respectively include lower metal layers having the buried U-shaped structure, and transistors having at least four different threshold voltages may be implemented.

In an implementation, the semiconductor devices 300, 300a, 300b, 300c, and 400, may be based on the fin structure and include the gate structures having various structures. In an implementation, when any gate structure is implemented so as to include a lower metal layer having a buried U-shaped structure while based on a fin structure and having various gate lengths, that gate structure would fall within the scope of the inventive concept regardless of its detailed structure, materials or the like.

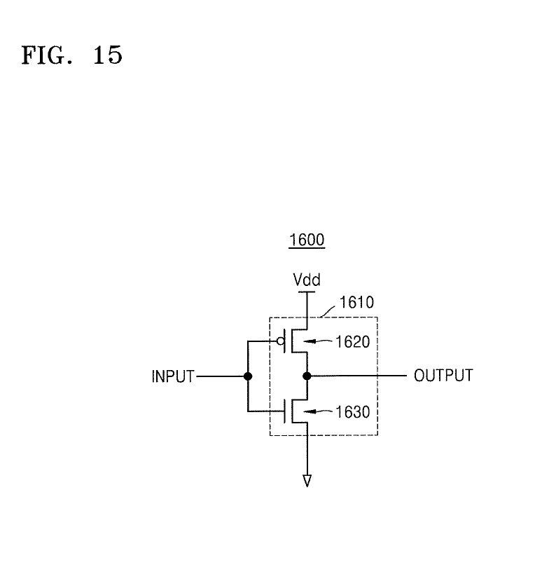

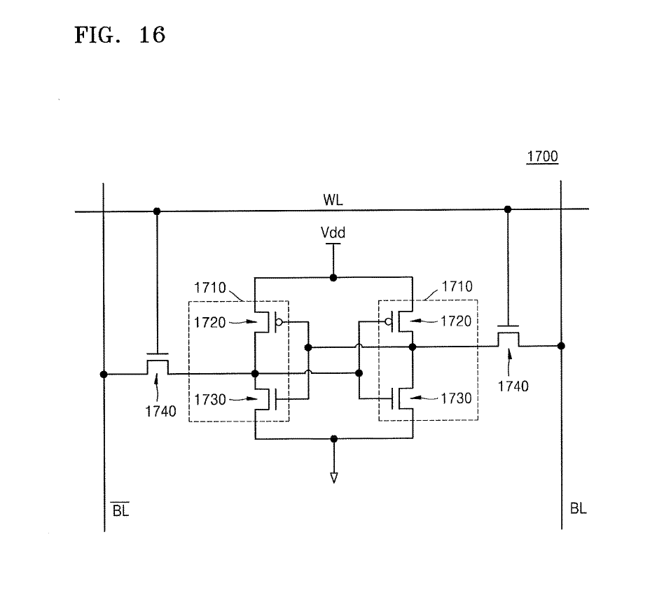

FIG. 15 illustrates a circuit diagram of a complementary metal-oxide-semiconductor (CMOS) inverter according to an embodiment.

Referring to FIG. 15, a CMOS inverter 1600 may include a CMOS transistor 1610. The CMOS transistor 1610 may include a PMOS transistor 1620 and an NMOS transistor 1630, which are connected to each other between a power supply terminal Vdd and a ground terminal. The CMOS transistor 1610 may include at least one semiconductor device of the semiconductor devices 100, 100a to 100c, 200, 300, 300a to 300c, and 400 according to the embodiments described with reference to FIGS. 1 to 3B, and 5 to 14, and semiconductor devices modified and changed therefrom.

FIG. 16 illustrates a circuit diagram of a CMOS SRAM device according to an embodiment of the inventive concept.

Referring to FIG. 16, a CMOS SRAM device 1700 may include a pair of drive transistors 1710. Each of the pair of drive transistors 1710 may include a PMOS transistor 1720 and an NMOS transistor 1730, which are connected to each other between a power supply terminal Vdd and a ground terminal. The CMOS SRAM device 1700 may further include a pair of transmission transistors 1740. A source of each of the transmission transistors 1740 may be cross-connected to a common node of the PMOS transistor 1720 and the NMOS transistor 1730 constituting the drive transistor 1710. The power supply terminal Vdd may be connected to a source of each of the PMOS transistors 1720, and the ground terminal may be connected to a source of each of the NMOS transistors 1730. A word line WL may be connected to gates of the pair of transmission transistors 1740, and a bit line BL and an inverted bit line may be respectively connected to drains of the pair of transmission transistors 1740.

At least one of the drive transistors 1710 and the transmission transistors 1740 of the CMOS SRAM device 1700 may include at least one semiconductor device of the semiconductor devices 100, 100a to 100c, 200, 300, 300a to 300c, and 400 according to the embodiments described with reference to FIGS. 1 to 3B, and 5 to 14, and semiconductor devices modified and changed therefrom.

FIGS. 17A to 17G illustrate cross-sectional views of stages in a process of manufacturing the semiconductor device of FIG. 2A. Content already described in FIGS. 1 to 2B may be briefly described or omitted.

Referring to FIG. 17A, first dummy gate structures 120d1 may be formed in the first region A on the substrate 101 and a second dummy gate structure 120d2 may be formed in the second region B. Further, spacers 130 may be formed at both sidewalls of each of the first dummy gate structures 120d1 and the second dummy gate structure 120d2. For example, a sacrificial insulating layer and a sacrificial gate layer may be formed on the substrate 101, a dummy insulating layer 121d and a dummy gate electrode 123d may be formed by patterning the sacrificial insulating layer and the sacrificial gate layer through a photolithography process, and thus the first dummy gate structures 120d1 in the first region A and the second dummy gate structure 120d2 in the second region B may be formed. In an implementation, the sacrificial insulating layer may be formed of an amorphous carbon layer (ACL) or an SOH containing a lot of carbon, and the sacrificial gate layer may be formed of polysilicon. The dummy insulating layer 121d may function as an etch stop film when the dummy gate electrode 123d is subsequently removed.

After the formation of the first dummy gate structure 120d1 and the second dummy gate structure 120d2, the spacers 130 may be formed at the both sidewalls of each of the first dummy gate structures 120d1 and the second dummy gate structure 120d2. After an insulating layer is provided to uniformly cover results on the substrate 101 and the substrate 101, the spacers 130 may be formed by removing an insulating layer formed on an upper surface of the dummy gate electrode 123d and the upper surface of the substrate 101 through a dry etching method and/or an etch-back method and maintaining the insulating layer formed on both sidewalls of each of the dummy insulating layer 121d and the dummy gate electrode 123d. In an implementation, the spacers 130 may be formed of an insulating material such as a nitride film or an oxynitride film. For example, the spacers 130 may be formed of a silicon nitride film or a silicon oxynitride film.

After the formation of the spacers 130, impurity regions, e.g., the source/drain regions 103, may be formed on an upper portion of the substrate 101 by performing an ion implantation process using the dummy gate structures 120d1 and 120d2 and the spacers 130 as masks. In an implementation, before the formation of the spacers 130, a lightly doped region may be formed by performing an ion implantation process.

As illustrated in the drawing, the first dummy gate structure 120d1 may have a first gate length W1, and the second dummy gate structure 120d2 may have a second gate length W2. The first gate length W1 may be smaller than the second gate length W2. In an implementation, the second gate length W2 may be at least two times the first gate length W1. In an implementation, the second gate length W2 may be at least five times the first gate length W1.

Referring to FIG. 17B, an insulating layer (which covers the substrate 101 and the results on the substrate 101) may be formed, and an interlayer insulating layer 140 may be formed by performing planarization on the insulating layer. The planarization of the insulating layer may be performed through a chemical mechanical polishing (CMP) process. Upper surfaces of the dummy gate structures 120d1 and 120d2 may be exposed through the planarization of the insulating layer. In an implementation, the interlayer insulating layer 140 may include at least one of a silicon oxide film, a silicon nitride film, a silicon oxynitride film, and a combination thereof, and may be formed of a material having a different etch selectivity from that of the spacers 130.

Referring to FIG. 17C, after the formation of the interlayer insulating layer 140, the dummy gate structures 120d1 and 120d2 may be removed. An upper surface Fs of the substrate 101 may be exposed through trenches T1 and T2 formed by removing the dummy gate structures 120d1 and 120d2. The spacers 130 and the interlayer insulating layer 140 may have an etch selectivity with respect to the dummy gate structures 120d1 and 120d2. Accordingly, the dummy gate structures 120d1 and 120d2 may be removed, e.g., through a wet etching method. In an implementation, removing the dummy gate structures 120d1 and 120d2 may be sequentially performed in the order of removing the dummy gate electrode 123d and then removing the dummy insulating layer 121d.

Referring to FIG. 17D, a high-k dielectric layer 121-1, a first metal layer 123-1, and a second metal layer 125-1 may be sequentially and conformally formed on the substrate 101 and the results on the substrate 101. The high-k dielectric layer 121-1, the first metal layer 123-1, and the second metal layer 125-1 may be formed through various deposition methods such as an ALD method, a CVD method, a PVD method, and the like. Materials of the high-k dielectric layer 121-1, the first metal layer 123-1, and the second metal layer 125-1 are the same as those described in FIGS. 1 to 2B.

After the formation of the high-k dielectric layer 121-1, the first metal layer 123-1, and the second metal layer 125-1, sacrificial layers 150a and 150b may be formed on the second metal layer 125-1. In an implementation, the sacrificial layers 150a and 150b may have a large thickness so as to completely fill a gap remaining after the formation of the second metal layer 125-1. In an implementation, the sacrificial layers 150a and 150b may be formed of, e.g., an organic thin film such as an SOH. Such sacrificial layers 150a and 150b may be removed by being etched by a UV irradiation etching method to a uniform thickness regardless of the pattern density as described above. For example, a uniform amount of the sacrificial layers 150a and 150b may be removed.

In an implementation, a height of the sacrificial layer 150a in the first region A and a height of the sacrificial layer 150b in the second region B may be different. For example, as illustrated in the drawing, an upper surface of the sacrificial layer 150a in the first region A may be higher than an upper surface of the sacrificial layer 150b in the second region B. This may be due to a loading effect caused by a difference between a pattern density of the first region A and a pattern density of the second region B. In an implementation, the loading effect may be prevented from occurring by forming the sacrificial layer to have a sufficiently large thickness or by adjusting a material of the sacrificial layer, e.g., components of the organic thin film. In such a case, the height of the sacrificial layer 150a in the first region A and the height of the sacrificial layer 150b in the second region B may be substantially the same.

In an implementation, the sacrificial layers 150a and 150b may be formed, e.g., by a spin coating method. In an implementation, the sacrificial layers 150a and 150b may also be formed by other deposition methods. In an implementation, the sacrificial layers 150a and 150b may be formed at a temperature in a range of, e.g., 150° C. to 300° C. Forming the sacrificial layers 150a and 150b in the range of 150° C. to 300° C. may help ensure that oxidation of the second metal layer 125-1 thereunder, e.g., TiN, may be minimized.

When the sacrificial layers 150a and 150b are formed of an SOH, an organic compound having a thickness of about 1,000 Å to 5,000 Å may be formed on the second metal layer 125-1 through the spin coating method or the other deposition methods. In an implementation, the organic compound may be formed of a hydrocarbon compound including an aromatic ring such as phenyl, benzene, or naphthalene, or a derivative thereof. In an implementation, the organic compound may be formed of a material having a relatively high carbon content in a range of about 85% by weight to about 99% by weight based on a total weight thereof. In an implementation, the sacrificial layers 150a and 150b formed of the SOH may be formed by baking the organic compound layer under a temperature in the range of about 150° C. to 300° C. In an implementation, the baking may be performed for about 60 seconds.

Referring to FIG. 17E, after the formation of the sacrificial layers, the sacrificial layers 150a and 150b may be removed by etching by UV irradiation to a predetermined thickness. In the etching of the sacrificial layers 150a and 150b by UV irradiation, the UV irradiation may be performed, e.g., with power in the range of, e.g., 1 W to 1,000 W. In an implementation, the UV irradiation may be performed with a baking process at a temperature in a range of, e.g., 150° C. to 300° C. As described in FIGS. 3A and 3B, in the UV irradiation etching method, the organic thin film may be etched to a uniform thickness or a uniform thickness or amount may be removed, regardless of the pattern density. In an implementation, the UV irradiation etching method may be performed by applying the same process condition to the first region A and the second region B, and a removed thickness or amount of the sacrificial layer 150a in the first region A and a removed thickness or amount of the sacrificial layer 150b in the second region B may be substantially the same.

After the etching of the sacrificial layers 150a and 150b by UV irradiation, a sacrificial layer 150a-1 remaining in the first region A may have a first height H1, and a sacrificial layer 150b-1 remaining in the second region B may have a second height H2. Here, the first height H1 and the second height H2 may be distances from the upper surface of the substrate 101 to upper surfaces of the remaining sacrificial layers 150a-1 and 150b-1, respectively. In an implementation, the first height H1 and the second height H2 may be, e.g., several nm to several tens of nm.

As illustrated in FIG. 17D, the sacrificial layer 150b in the first region A and the sacrificial layer 150b in the second region B may be removed to the same thickness (e.g., the same amount may be removed) by the UV irradiation etching method while the sacrificial layer 150b in the first region A is formed at a higher level than the sacrificial layer 150b in the second region B due to the loading effect, an initial difference between the heights thereof may be maintained as it is in the remaining sacrificial layers 150a-1 and 150b-1. Therefore, the first height H1 may be greater than the second height H2. In an implementation, the difference between the heights thereof may not occur by forming the sacrificial layers 150a and 150b to have a sufficiently large thickness or by adjusting components of the sacrificial layers 150a and 150b. In such a case, the heights of the remaining sacrificial layers 150a-1 and 150b-1 may be substantially the same.

As described in the description of FIG. 4, the UV irradiation etching method may rarely cause damage to other material layers. Therefore, the second metal layer 125-1 and the first metal layer 123-1, which are lower layers of or relative to the sacrificial layers 150a and 150b, may not be damaged after the etching by the UV irradiation. For example, after the etching of the sacrificial layers 150a and 150b through UV irradiation, the second metal layer 125-1 and the first metal layer 123-1 may be respectively maintained to have identical thicknesses and profiles before the etching of the sacrificial layers 150a and 150b.

Referring to FIG. 17F, portions of the high-k dielectric layer 121-1, the first metal layer 123-1, and the second metal layer 125-1 (exposed through a wet etching method) may be removed using the remaining sacrificial layers 150a-1 and 150b-1 as protection layers. For example, the high-k dielectric layer 121-1, the first metal layer 123-1, and the second metal layer 125-1 on side surfaces of the spacers 130 and on the interlayer insulating layer 140 may be removed using an etchant such as N₂H₂. Due to a property of the wet etching method, portions of the high-k dielectric layer 121-1, the first metal layer 123-1, and the second metal layer 125-1 that are covered by the remaining sacrificial layers 150a-1 and 150b-1 may be maintained without being removed. Meanwhile, only the exposed portions of the first metal layer 123-1 and the second metal layer 125-1 may be removed by appropriately adjusting the etchant, and the high-k dielectric layer 121-1 may also be maintained without being removed.

After the removal of the exposed portions of the high-k dielectric layer 121-1, the first metal layer 123-1, and the second metal layer 125-1, the remaining sacrificial layers 150a-1 and 150b-1 may be removed through, e.g., an ashing method and a strip method. In an implementation, the remaining sacrificial layers 150a-1 and 150b-1 may be removed through a UV irradiation etching method. The process of removing the remaining sacrificial layers 150a-1 and 150b-1 by the ashing method and the strip method or the UV irradiation etching method may rarely cause damage to the second metal layers 125a and 125b.

Lower metal layers 127a and 127b having the buried U-shaped structure, which are the same as those illustrated in FIG. 2A, may be formed by removing the remaining sacrificial layers 150a-1 and 150b-1. Heights of protruding portions at the both side surfaces of each of the lower metal layers 127a and 127b may depend on heights of the remaining sacrificial layers 150a-1 and 150b-1. For example, the protruding portions at both side surfaces of the first lower metal layer 127a may have the first height H1, and the protruding portions at both side surfaces of the second lower metal layer 127b may have the second height H2.

Referring to FIG. 17G, after the formation of the lower metal layers 127a and 127b, metal layers 129a-1 and 129b-1 may be formed on the lower metal layers 127a and 127b, respectively. In an implementation, the metal layers 129a-1 and 129b-1 may have a large thickness so as to completely fill the remaining gap between the spacers 130. In an implementation, the metal layers 129a-1 and 129b-1 may be formed of, e.g., TiN. In an implementation, the metal layers 129a-1 and 129b-1 may be formed of, e.g., TaN, TiAlC, TiAlN, TiAlC—N, TiAl, TaAlC, TaAlN, TaAlC—N, TaA, and the like.

As illustrated in the drawing, a height of the metal layer 129a-1 formed in the first region A may be greater than a height of the metal layer 129b-1 formed in the second region B by a loading effect. In an implementation, the loading effect may be prevented from occurring by forming the metal layers 129a-1 and 129b-1 to have a sufficiently large thickness or by adjusting components thereof.

After the formation of the metal layers 129a-1 and 129b-1, a planarization process may be performed to expose an upper surface of the interlayer insulating layer 140. The planarization process may be performed, e.g., through a CMP process. Upper metal layers 129a and 129b, e.g., the same as those illustrated in FIG. 2A, which are electrically separated from each other, may be formed through the planarization process. Further, gate structures 120a and 120b may be formed through the formation of the upper metal layers 129a and 129b.

After the formation of the gate structures 120a and 120b, subsequent semiconductor processes may be performed. The subsequent semiconductor processes may include various processes. For example, the subsequent semiconductor processes may include a deposition process, an etching process, an ion process, a cleaning process, and the like. Here, the deposition process may include various processes of forming a material layer such as a CVD process, a sputtering process, a spin coating process, and the like. The ion process may include an ion implantation process, a diffusion process, a heat treatment process, and the like. Integrated circuits and wirings required for the semiconductor device may be formed by performing such subsequent semiconductor processes.

In an implementation, the subsequent semiconductor processes may include a packaging process in which the semiconductor device is mounted on a printed circuit board (PCB) and sealed by a sealing member. In an implementation, the subsequent semiconductor processes may also include a test process for testing a semiconductor device or a semiconductor package. The semiconductor device or the semiconductor package may be completed by performing such subsequent semiconductor processes.

In the method of manufacturing the semiconductor device in the present embodiment, the height of the remaining sacrificial layer or amount of sacrificial layer removed may be uniformly maintained by removing the sacrificial layer through the UV irradiation etching method to a uniform thickness regardless of the pattern density, and thus the height of the lower metal layer may also be uniformly maintained. Therefore, an electrical characteristic of a transistor including a gate structure including such a lower metal layer may be uniformly maintained. For example, a threshold voltage of the transistor formed with the gate structure including the lower metal layer having a buried U-shaped structure may be changed depending on a length of a gate, and uniformity in which transistors having the same length have the same threshold voltage may be maintained.

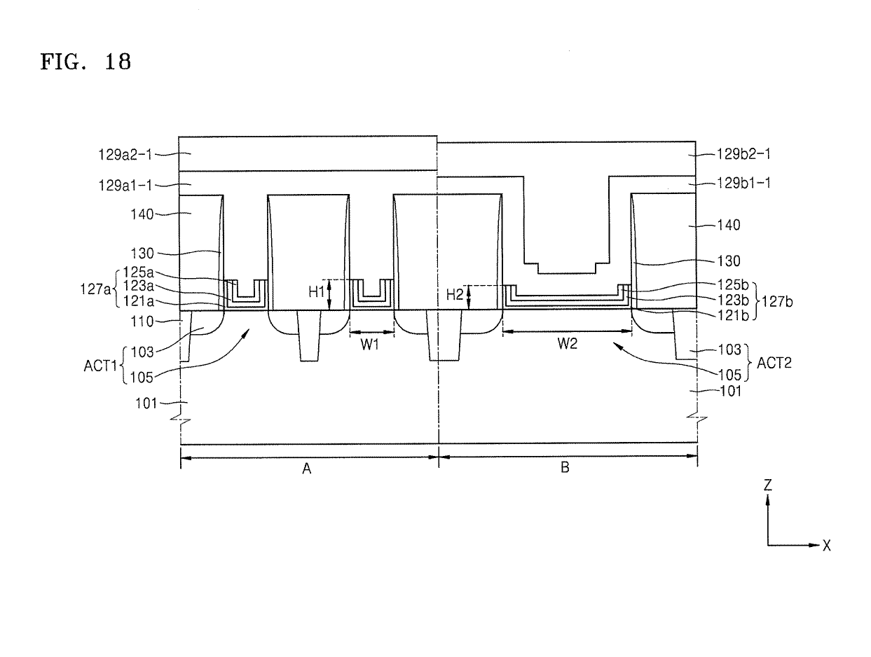

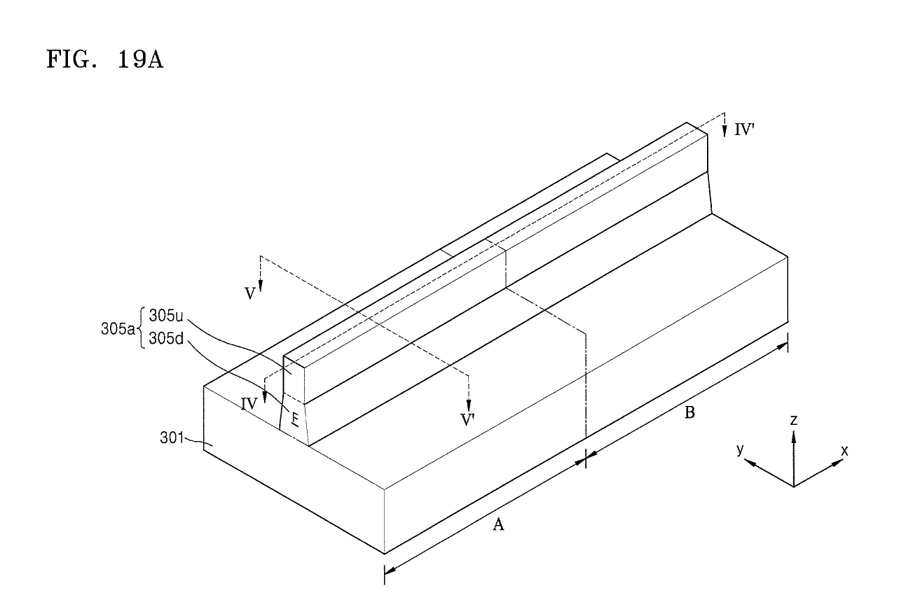

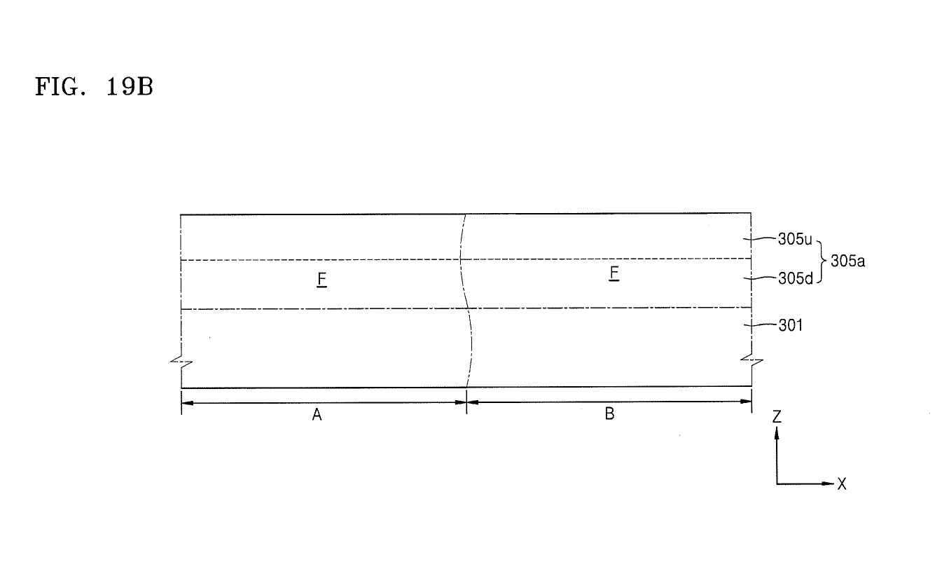

FIG. 18 illustrates a cross-sectional view of a stage in a process of manufacturing the semiconductor device of FIG. 7. Content already described in FIGS. 1 to 2B, 7, and 17A to 17G may be briefly described or omitted.

Referring to FIG. 18, after the lower metal layers 127a and 127b are formed through the processes in FIGS. 17A to 17B, metal layers 129a1-1 and 129b1-1 may be formed on the lower metal layers 127a and 127b. However, unlike in FIG. 17G, the metal layer 129a1-1 may completely fill the gap in the first region A, and the metal layer 129b1-1 may only partially fill the gap in the second region B. For example, the metal layer 129b1-1 in the second region B may have a structure that covers upper surfaces of the second high-k dielectric layer 121b and the second lower metal layer 127b and side surfaces of the spacers 130 to a predetermined thickness. Materials and the like of the metal layers 129a1-1 and 129b1-1 may be the same as those described in the description of FIG. 17G.

Then, gap fill metal layers 129a2-1 and 129b2-1 may be respectively formed on the metal layers 129a1-1 and 129b1-1. The gap fill metal layers 129a2-1 and 129b2-1 may be formed to a thickness that may completely fill the remaining gap in the second region B. In an implementation, the gap fill metal layers 129a1-1 and 129b1-1 may be formed of, e.g., tungsten (W). In an implementation, the gap fill metal layers 129a1-1 and 129b1-1 may be formed of various suitable metals to fill the gap, e.g., a material selected from a group consisting of a metal nitride such as TiN, TaN, or the like, Al, a metal carbide, a metal silicide, a metal aluminum carbide, a metal aluminum nitride, a metal silicon nitride, and the like.

After the formation of the gap fill metal layers 129a2-1 and 129b2-1, a gap fill metal layer 129b2 may be formed by exposing the upper surface of the interlayer insulating layer 140 through a planarization process such as a CMP process. Gate structures 120a and 120b3 the same as illustrated in FIG. 7 may be formed through the formation of the gap fill metal layer 129b2. Then, a semiconductor device or a semiconductor package may be completed by performing subsequent semiconductor processes.

FIGS. 19A to 27C illustrate perspective views and cross-sectional views of stages in a process of manufacturing the semiconductor device of FIG. 9. Content already described in FIGS. 9 to 10B and 17A to 17G may be briefly described or omitted.

Referring to FIGS. 19A to 19C, a fin 305a having a structure that protrudes from a substrate 301 may be formed by etching an upper portion of the substrate 301. The fin 305a may extend in a first direction (an X direction) on the substrate 301. As illustrated in the drawing, the fin 305a may include a lower fin portion 305d and an upper fin portion 305u. The lower fin portion 305d may be a portion to be covered by a subsequent device isolation layer.

In an implementation, the fin 305a may be formed in a first region A and a second region B on the substrate 301. In FIG. 19A, the fin 305a extends in the same direction in each of the first region A and the second region B. In an implementation, the fin 305a in the first region A and the fin 305a in the second region B may also extend in different directions. Further, in each of the first region A and the second region B, a plurality of fins may be formed along a second direction (a Y direction) at a predetermined interval.

In addition, structures and materials of the substrate 301 and the fin 305a are the same as those of the semiconductor device 300 described in FIGS. 9 to 10B.

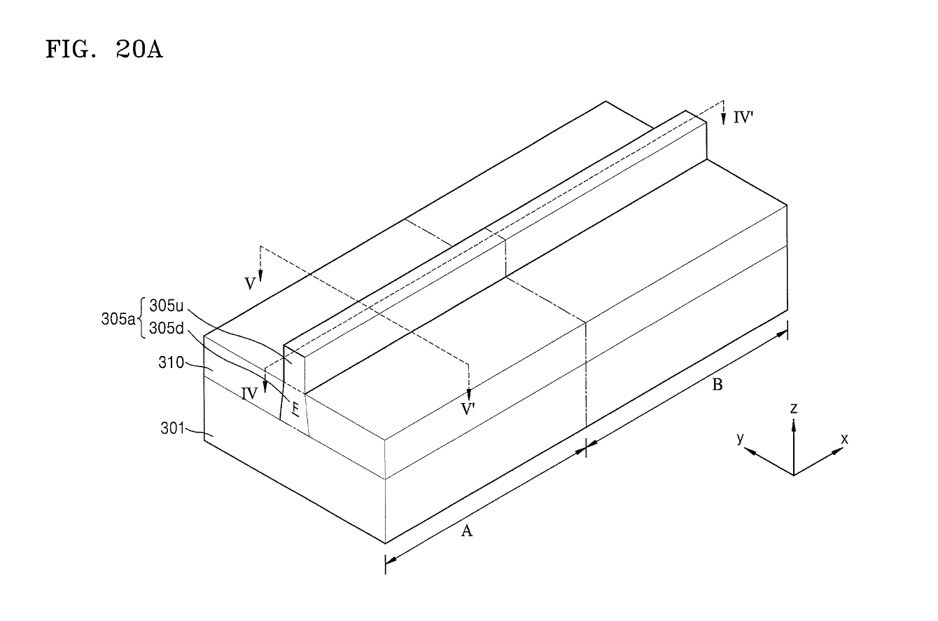

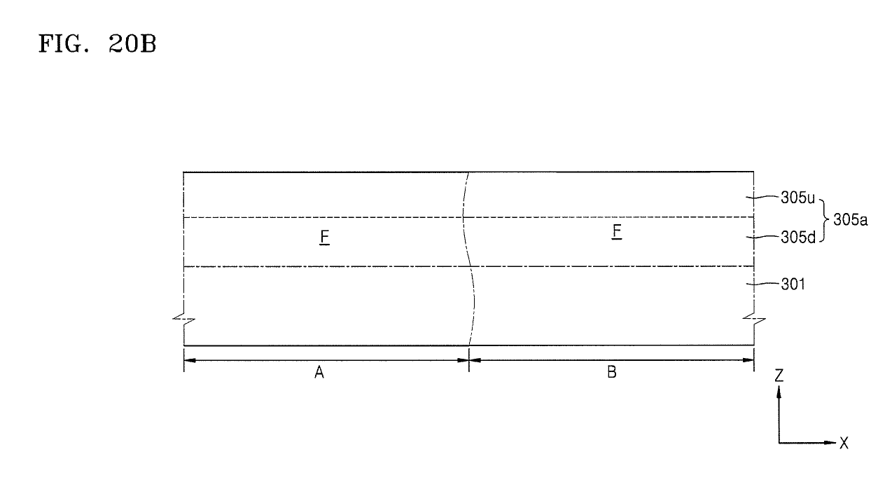

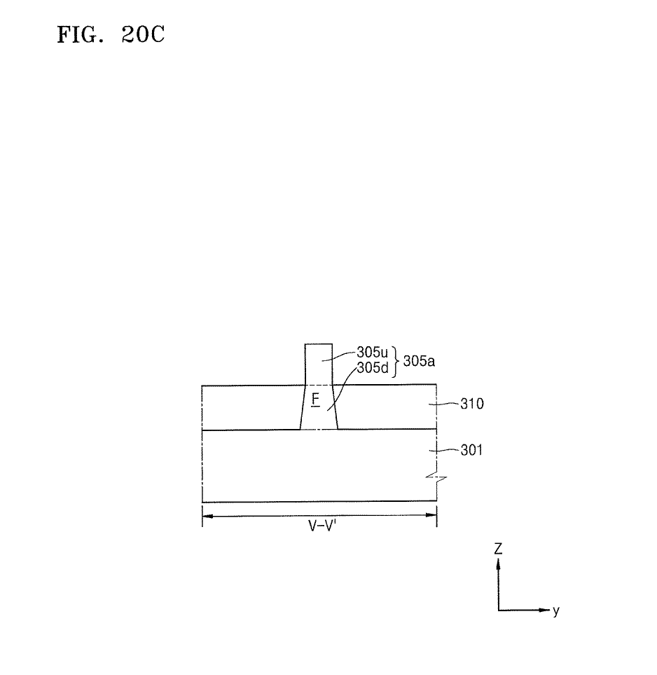

Referring to FIGS. 20A to 20C, after the formation of the fin 305a, a device isolation layer 310 that covers lower portions of both side surfaces of the fin 305a may be formed. In an implementation, the device isolation layer 310 may be formed, an upper portion of the fin 305a, e.g., the upper fin portion 305u, and may have a structure that protrudes from the device isolation layer 310.

The device isolation layer 310 may be formed by removing an upper portion of the device isolation layer 310 so that the upper portion of the fin 305a protrudes after an insulating layer which covers the substrate 301 and results on the substrate 301 is formed and planarized. In addition, a material and the like of the device isolation layer 310 are the same as those of the semiconductor device 300 described in FIGS. 9 to 10B.

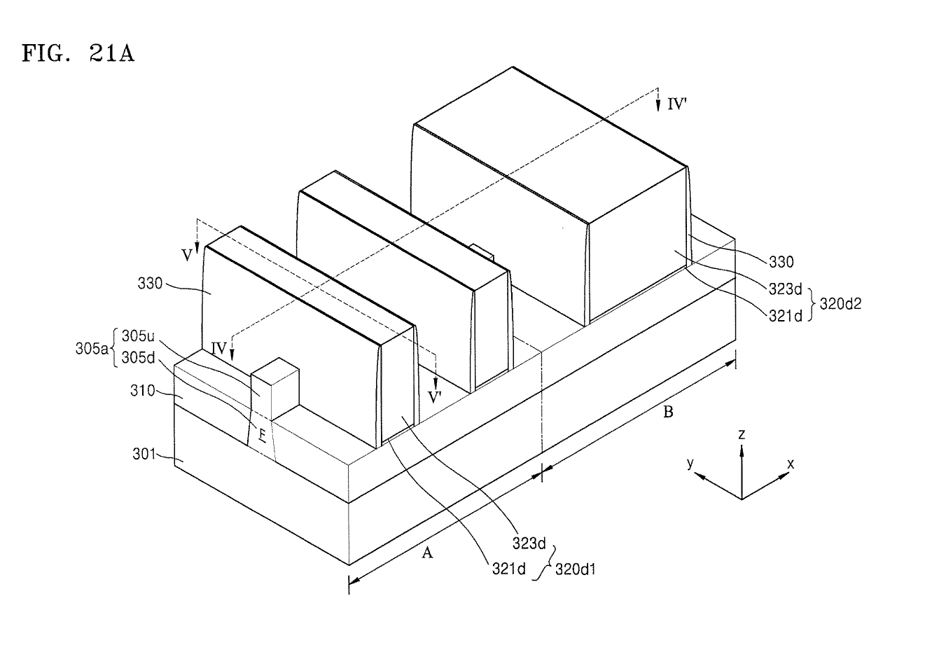

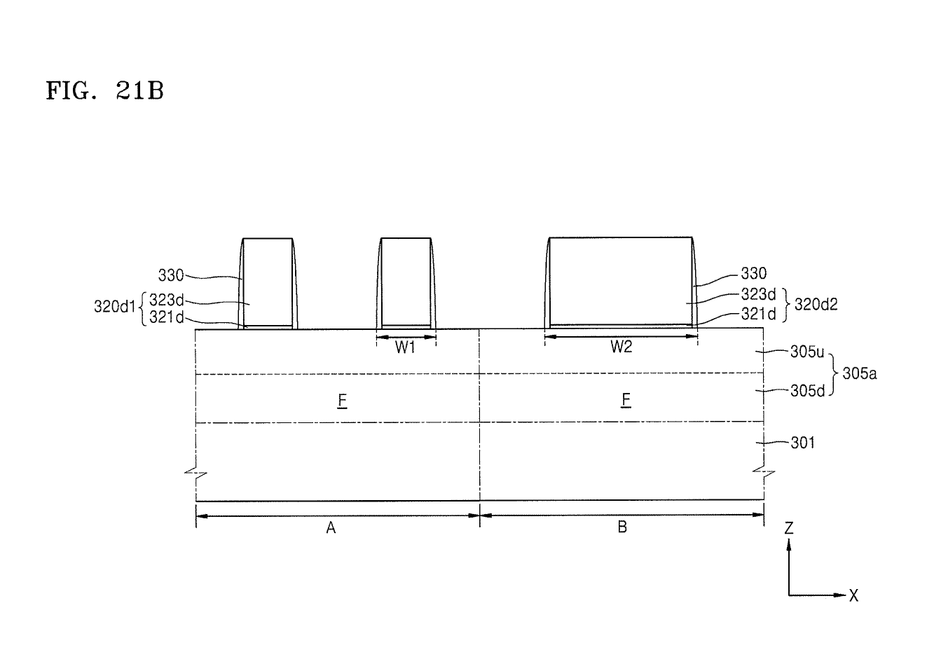

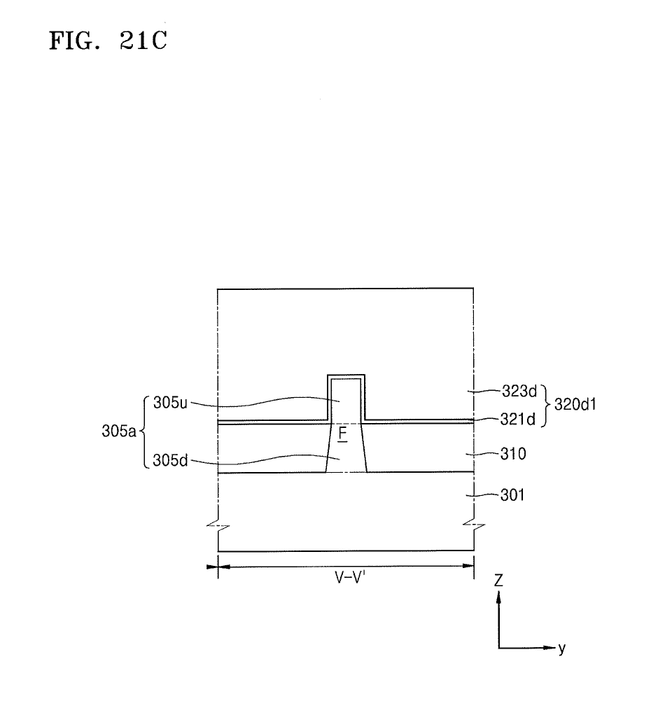

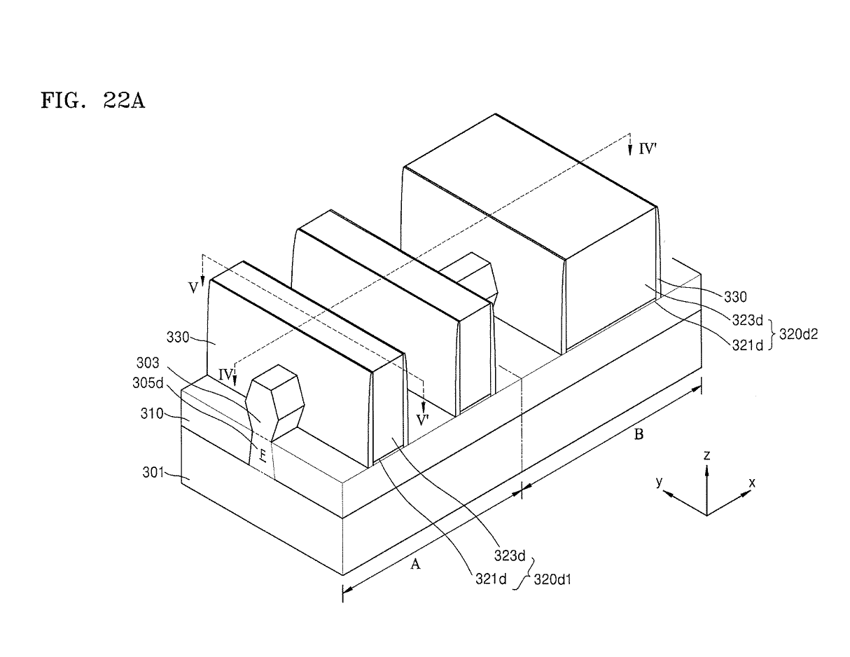

Referring to FIGS. 21A to 21C, after the formation of the device isolation layer 310, dummy gate structures 320d1 and 320d2 respectively including a dummy insulating layer 321d and a dummy gate electrode 323d may be formed, and spacers 330 may be formed at both side surfaces of each of the dummy gate structures 320d1 and 320d2. The dummy gate structures 320d1 and 320d2 may have, e.g., have a structure that extends in the second direction (the Y direction). As illustrated in the drawing, the dummy gate structures 320d1 and 320d2 may include a first dummy gate structure 320d1 in the first region A and a second dummy gate structure 320d2 in the second region B.

Processes for forming the dummy gate structures 320d1 and 320d2 and the spacers 330 may be similar to those described in the description of FIG. 17A. However, the fin 305a which protrudes from the substrate 301 is formed, the device isolation layer 310 which surrounds the both side surfaces of the lower fin portion 305d of the fin 305a is formed, and thus the dummy gate structures 320d1 and 320d2 and the spacers 330 may be formed on the device isolation layer 310 to have a structure which surrounds an upper surface and side surfaces of the upper fin portion 305u of the fin 305a.

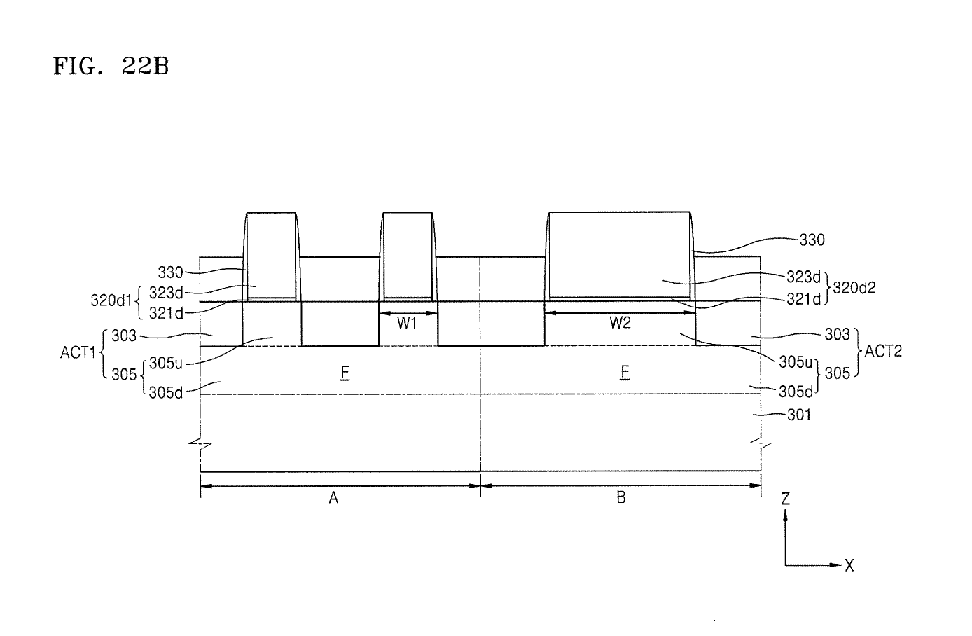

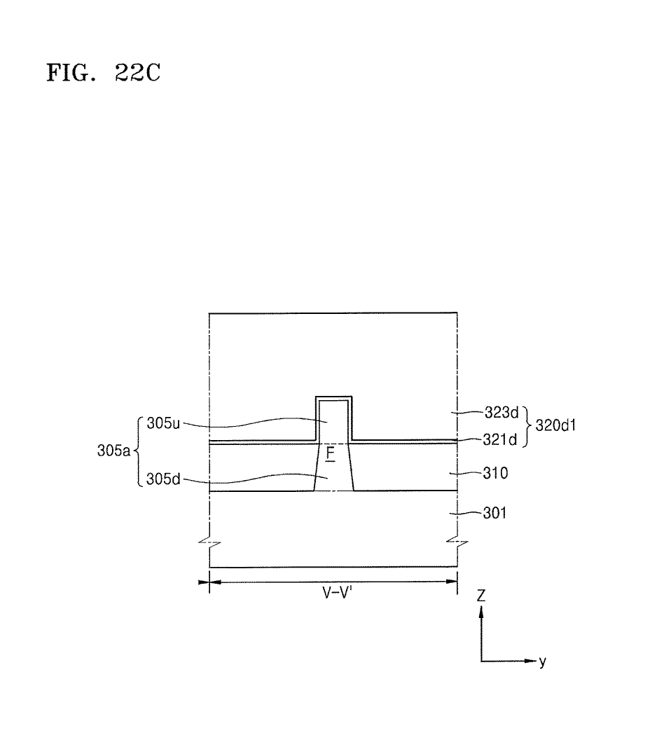

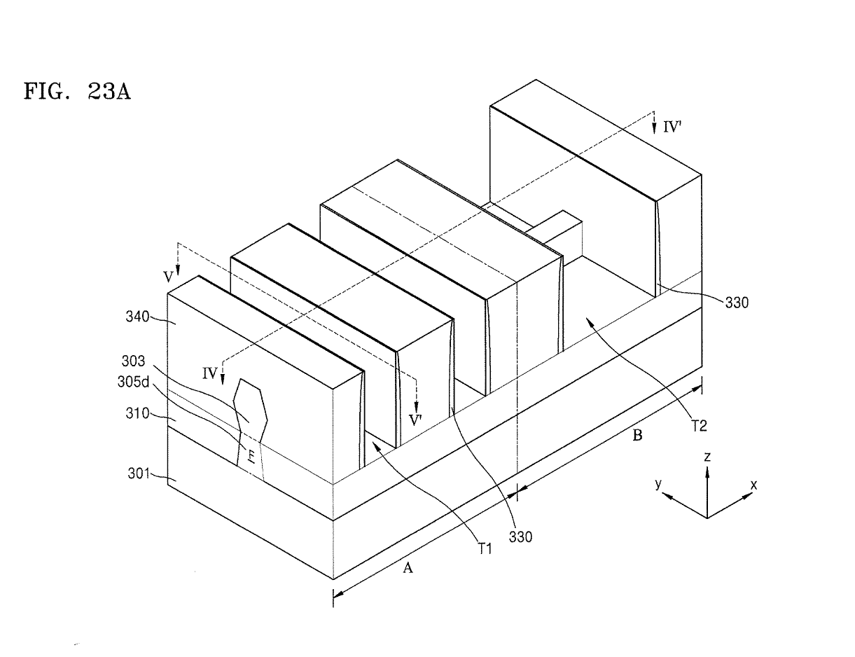

Referring to FIGS. 22A to 22C, source/drain regions 303 may be formed by removing the upper fin portion 305u protruding from the device isolation layer 310 at the both side surfaces of each of the dummy gate structures 320d1 and 320d2. For example, the source/drain regions 303 may be formed by removing the upper fin portion 305u protruding from the device isolation layer 310 and growing an epitaxial layer on the lower fin portion 305d. In an implementation, the source/drain regions 303 may include at least one of silicon germanium (SiGe), germanium (Ge), silicon (Si), and silicon carbide (SiC) which are grown epitaxially on the lower fin portion 305d. Meanwhile, at the same time with an epitaxial growth process or after the epitaxial growth process, the source/drain regions 303 may be doped with an impurity. In an implementation, the source/drain regions 303 are formed as described above, and the first fin active region ACT1 in the first region A and the second fin active region ACT2 in the second region B may be completed. The fin active regions ACT1 and ACT2 are the same as those described in FIGS. 9 to 10B.

As illustrated in FIG. 22B, upper surfaces of the source/drain regions 303 may be higher than an upper surface of the upper fin portion 305u under the dummy gate structures 320d1 and 320d2. In an implementation, the source/drain regions 303 may cover lower portions of the side surfaces of the spacers 330.

In an implementation, the upper fin portion 305u may not be removed, and the source/drain regions 303 may also be formed based on the upper fin portion 305u. In such a case, the source/drain regions 303 may maintain an initial shape of the upper fin portion 305u or may have a slightly different shape from the initial shape of the upper fin portion 305u through the epitaxial growth process.

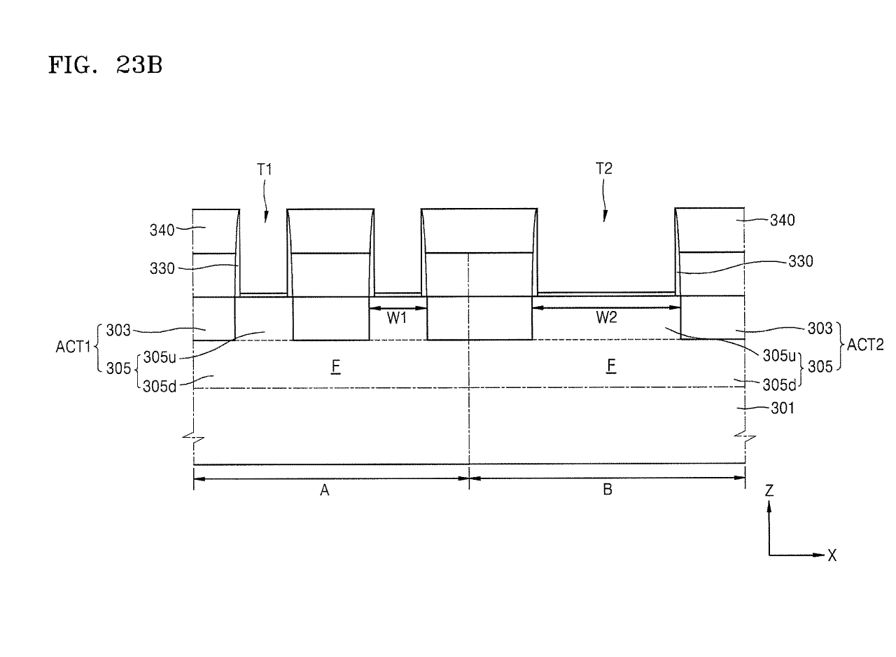

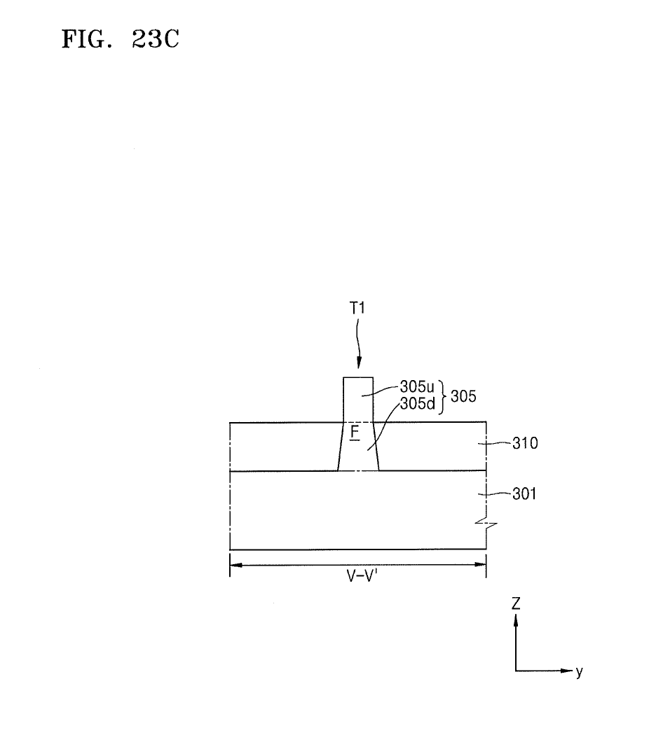

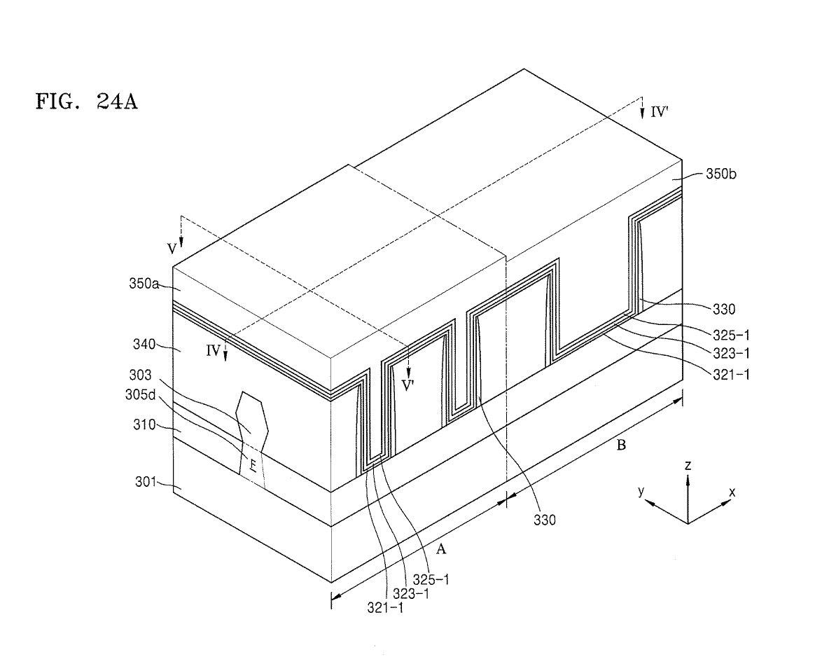

Referring to FIGS. 23A to 23C, after the formation of the source/drain regions 303, an interlayer insulating layer 340 may be formed by forming an insulating layer which covers the substrate 301 and the results on the substrate 301 and performing planarization on the insulating layer. A material and the like of the interlayer insulating layer 340 are the same as those described in FIGS. 9 to 10B.

After the formation of the interlayer insulating layer 340, the dummy gate structures 320d1 and 320d2 may be removed. The removal of the dummy gate structures 320d1 and 320d2 is the same as that described in FIG. 17C. As illustrated in FIG. 23C, the upper surface and the side surfaces of the upper fin portion 305u may be exposed through trenches T1 and T2 formed by the removal of the dummy gate structures 320d1 and 320d2.

In an implementation, the side surfaces of the spacers 330 after the removal of the dummy gate structures 320d1 and 320d2 may be viewed as edges of the upper surface and the side surfaces of the upper fin portion 305u when seen in a cross section of line V-V′, but are not illustrated.

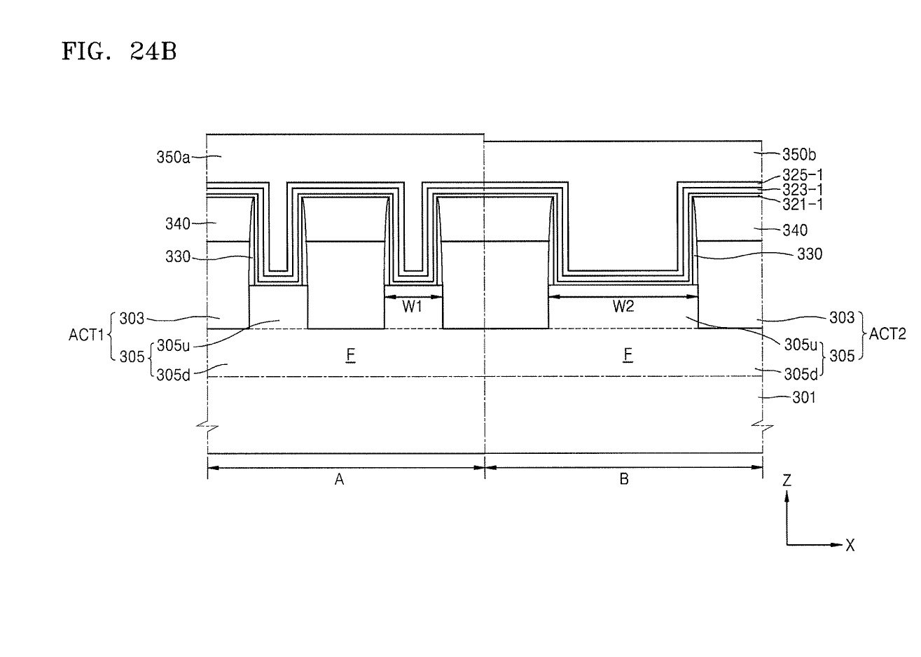

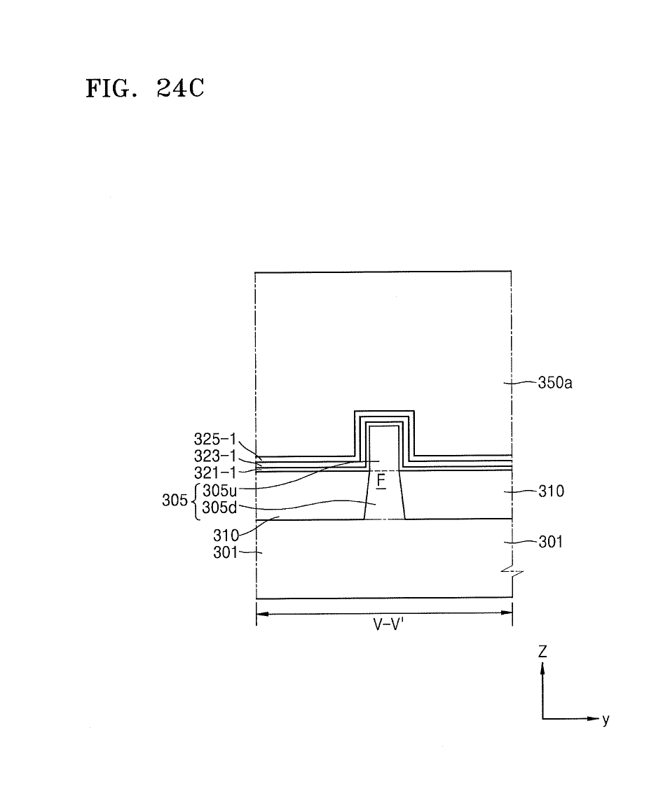

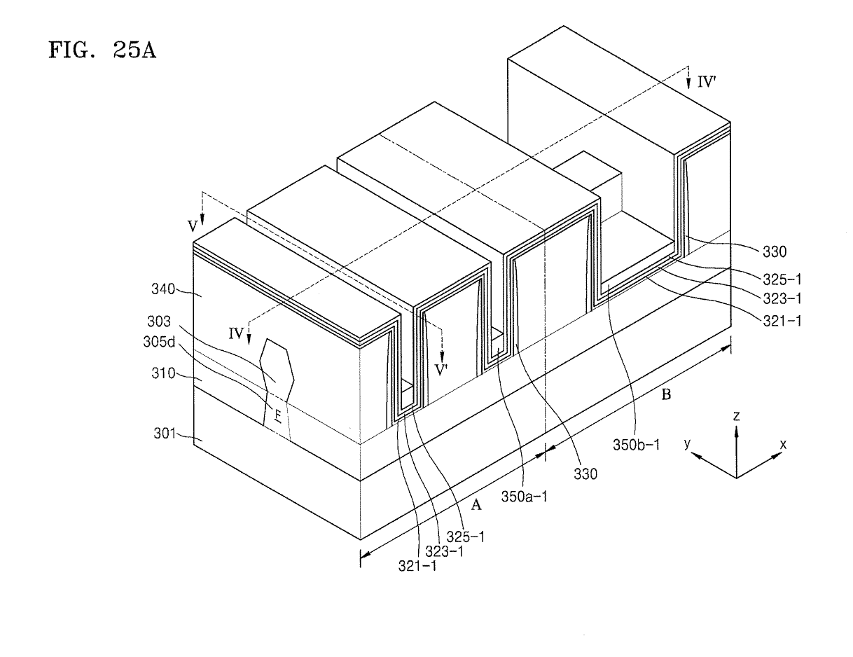

Referring to FIGS. 24A to 24C, a high-k dielectric layer 321-1, a first metal layer 323-1, and a second metal layer 325-1 may be sequentially and conformally formed on the substrate 301 and the results on the substrate 301. The high-k dielectric layer 321-1, the first metal layer 323-1, and the second metal layer 325-1 may be formed through various deposition methods such as an ALD method, a CVD method, a PVD method, and the like. Materials of the high-k dielectric layer 321-1, the first metal layer 323-1, and the second metal layer 325-1 are the same as those described in FIGS. 1 to 2B.

Then, sacrificial layers 350a and 350b may be formed on the second metal layer 325-1. The sacrificial layers 350a and 350b may have a large thickness so as to completely fill a gap remaining after the formation of the second metal layer 325-1. In an implementation, the sacrificial layers 350a and 350b may be formed of, e.g., an organic thin film such as an SOH. Meanwhile, a height of the sacrificial layer 350a in the first region A and a height of the sacrificial layer 350b in the second region B may be different. For example, as illustrated in the drawing, an upper surface of the sacrificial layer 350a in the first region A may be higher than an upper surface of the sacrificial layer 350b in the second region B. This is due to a loading effect caused by a difference between a pattern density of the first region A and a pattern density of the second region B. In an implementation, the loading effect may be prevented from occurring by forming the sacrificial layers to have a sufficiently large thickness or by adjusting materials of the sacrificial layers, for example, components of the organic thin film. In such a case, the height of the sacrificial layer 350a in the first region A and the height of the sacrificial layer 350b in the second region B may be formed substantially the same.

In an implementation, the sacrificial layers 350a and 350b may be formed, e.g., by a spin coating method. In an implementation, the sacrificial layers 350a and 350b may be formed by other deposition methods. The sacrificial layers 150a and 150b may be formed at a temperature in a range of, e.g., 150° C. to 300° C. A detailed method of forming the sacrificial layers 350a and 350b formed of an SOH is the same as that described in the description of FIG. 17D.

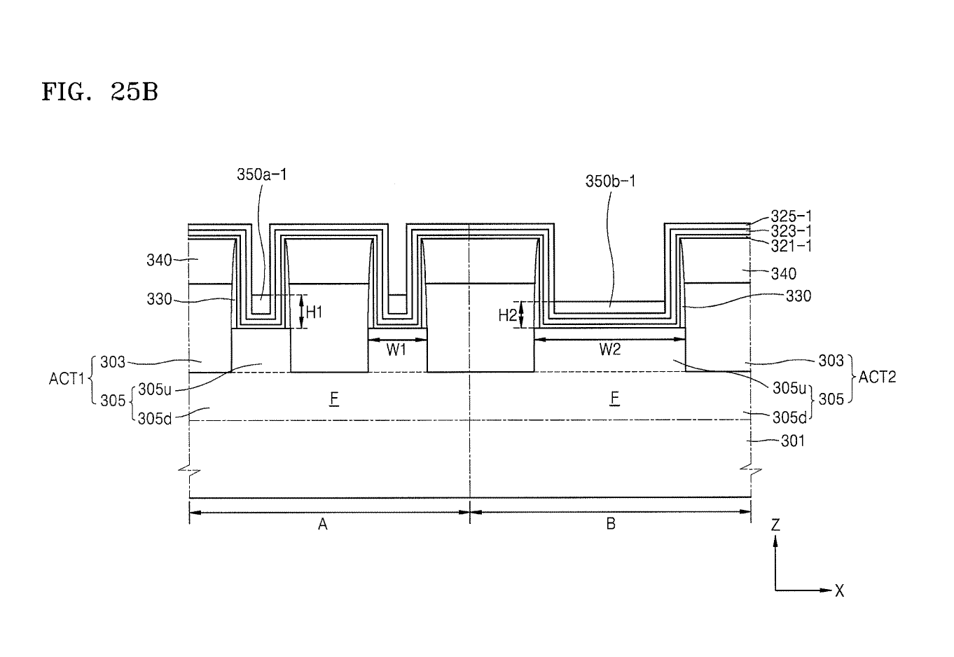

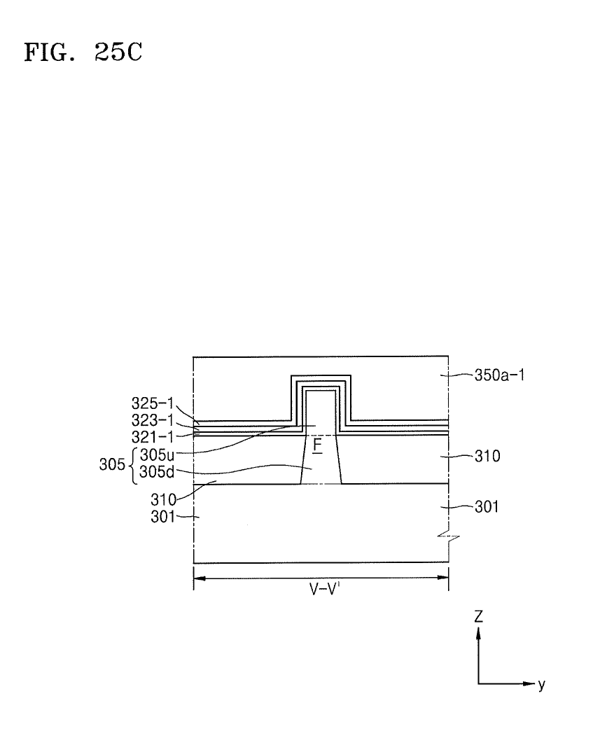

Referring to FIGS. 25A to 25C, after the formation of the sacrificial layer, the sacrificial layers 350a and 350b may be removed by etching by UV irradiation to a predetermined thickness. In the etching of the sacrificial layers 350a and 350b by UV irradiation, the UV irradiation may be performed, e.g., with power in the range of 1 W to 1,000 W. In an implementation, the UV irradiation may also be performed with a baking process at a temperature in the range of 150° C. to 300° C. As described in FIGS. 3A and 3B, in the UV irradiation etching method, the organic thin film may be etched to have a uniform thickness or a uniform amount of the organic thin film may be removed regardless of a pattern density. In an implementation, the UV irradiation etching method may be performed by applying the same process condition to the first region A and the second region B, and thus a removed thickness of the sacrificial layer 350a in the first region A and a removed thickness of the sacrificial layer 350b in the second region B may be substantially the same.

After the etching of the sacrificial layers 350a and 350b by UV irradiation, a sacrificial layer 350a-1 remaining in the first region A may have a first height H1, and a sacrificial layer 350b-1 remaining in the second region B may have a second height H2. Here, the first height H1 and the second height H2 may be distances from the upper surface of the upper fin portion 305u to the upper surfaces of the remaining sacrificial layers 350a-1 and 350b-1, respectively. Meanwhile, when a cross section perpendicular to the second direction (the Y direction) does not exist in the fin 305, the first height H1 and the second height H2 may be lengths from an upper surface of the device isolation layer 310 to the upper surfaces of the remaining sacrificial layers 350a-1 and 350b-1, respectively. In an implementation, the first height H1 and the second height H2 may be, e.g., several nm to several tens of nm.

As described in the description of FIG. 17E, due to a difference between initial heights of the sacrificial layers 350a and 350b by the loading effect and the removal to the uniform thickness by the UV irradiation etching method, the first height H1 may be greater than the second height H2. However, as described above, when there is no difference between the initial heights of the sacrificial layers 350a and 350b by forming the sacrificial layers 350a and 350b to have a sufficiently large thickness or adjusting components of the sacrificial layers 350a and 350b, heights of the remaining sacrificial layers 350a-1 and 350b-1 may be substantially the same.

As described in the description of FIG. 4, the UV irradiation etching method may not or only rarely cause damage to other material layers. Therefore, the second metal layer 325-1 and the first metal layer 323-1, which are lower layers of or are below the sacrificial layers 350a and 350b, may not be damaged after the etching by UV irradiation. For example, after the etching of the sacrificial layers 350a and 350b through UV irradiation, the second metal layer 325-1 and the first metal layer 323-1 may be respectively maintained to have identical thicknesses and profiles before the etching of the sacrificial layers 350a and 350b.

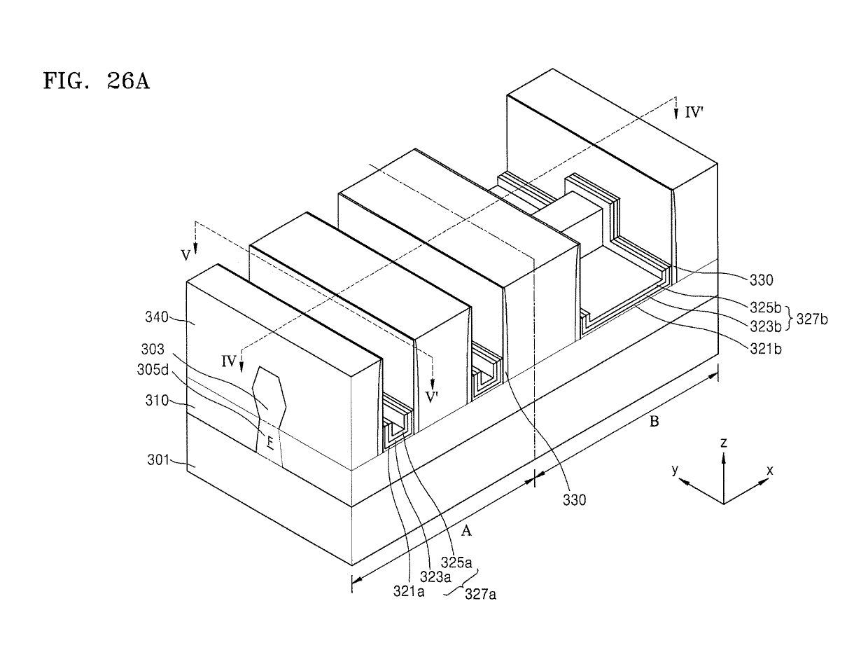

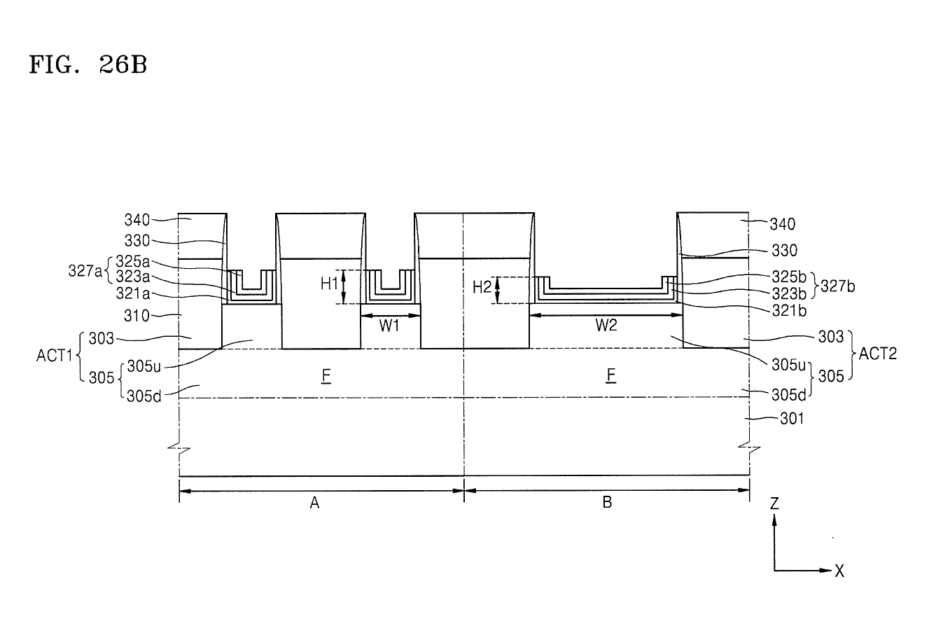

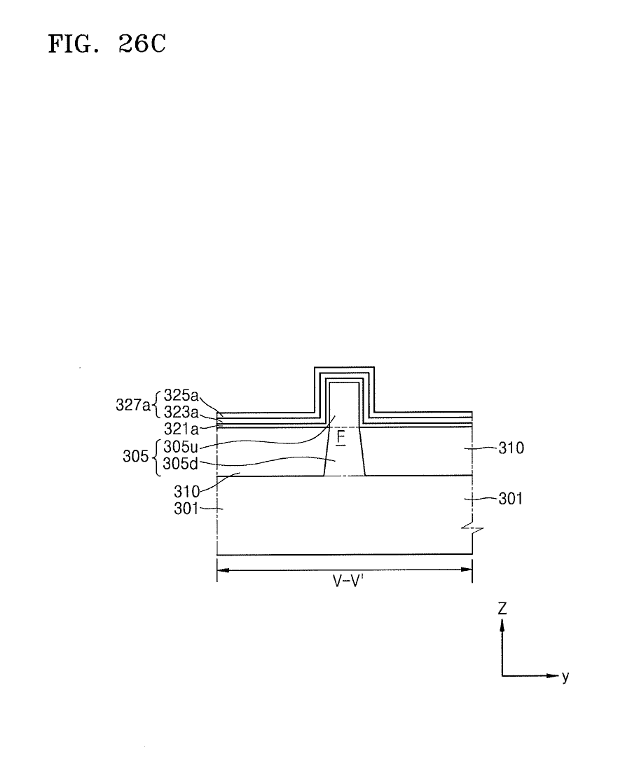

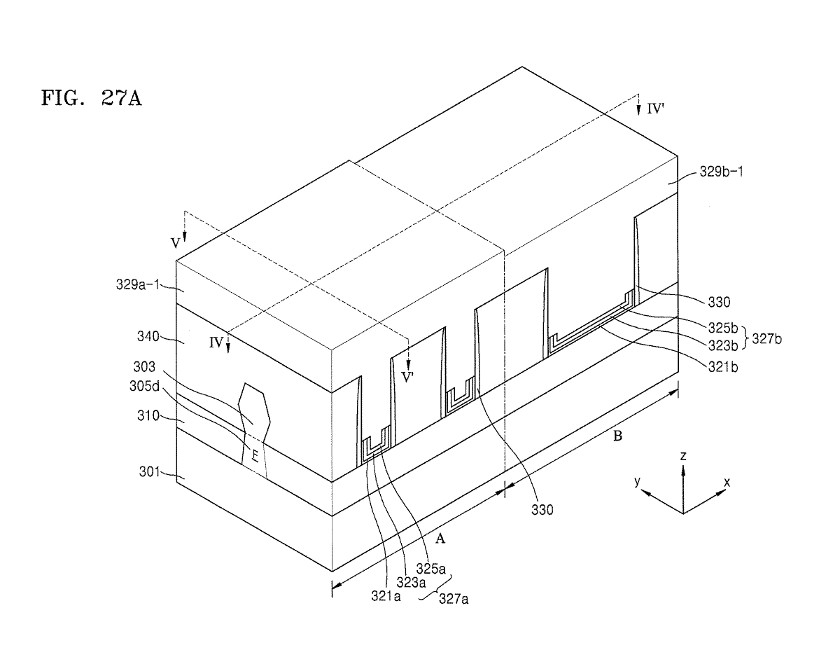

Referring to FIGS. 26A to 26C, portions of the high-k dielectric layer 321-1, the first metal layer 323-1, and the second metal layer 325-1 that are exposed through a wet etching method may be removed using the remaining sacrificial layers 350a-1 and 350b-1 as protection layers. For example, the high-k dielectric layer 321-1, the first metal layer 323-1, and the second metal layer 325-1 on the side surfaces of the spacers 330 and on the interlayer insulating layer 340 may be removed using an etchant such as N₂H₂. Due to a property of the wet etching method, portions of the high-k dielectric layer 321-1, the first metal layer 323-1, and the second metal layer 325-1, which are covered by the remaining sacrificial layers 350a-1 and 350b-1, may be maintained without being removed. In an implementation, only the exposed portions of the first metal layer 323-1 and the second metal layer 325-1 may be removed by appropriately adjusting the etchant, and the high-k dielectric layer 321-1 may also be maintained without being removed.

In an implementation, after the removal of the exposed portions of the high-k dielectric layer 321-1, the first metal layer 323-1, and the second metal layer 325-1, the remaining sacrificial layers 350a-1 and 350b-1 may be removed through an ashing method or a strip method. In an implementation, the remaining sacrificial layers 350a-1 and 350b-1 may also be removed through a UV irradiation etching method. Lower metal layers 327a and 327b having a buried U-shaped structure the same as illustrated in FIG. 10A may be formed by removing the remaining sacrificial layers 350a-1 and 350b-1. Heights of protruding portions at both side surfaces of each of the lower metal layers 327a and 327b may depend on the heights of the remaining sacrificial layers 350a-1 and 350b-1. For example, the protruding portions at the both side surfaces of the first lower metal layer 327a may have a first height H1, and the protruding portions at the both side surfaces of the second lower metal layer 327b may have a second height H2.

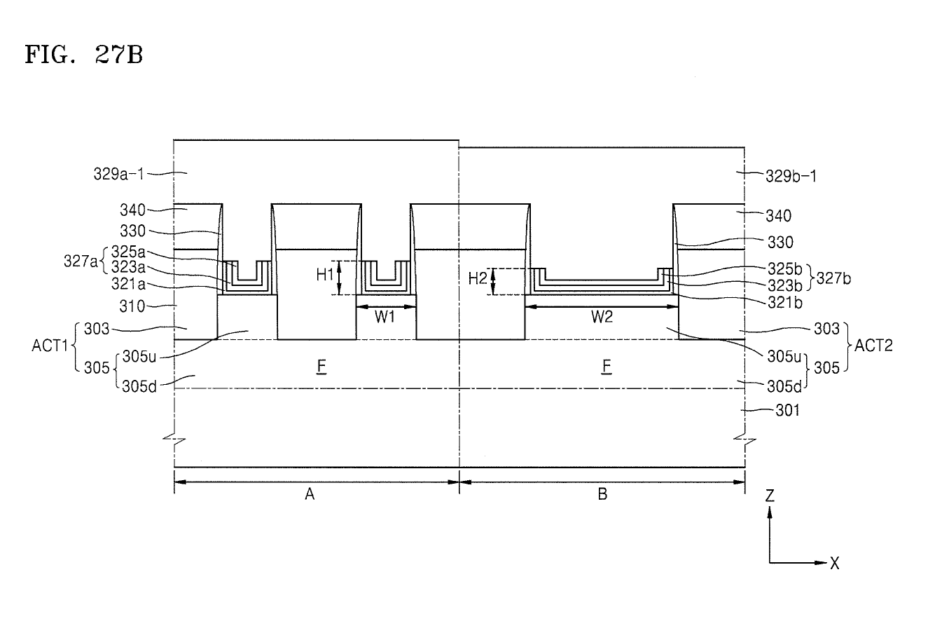

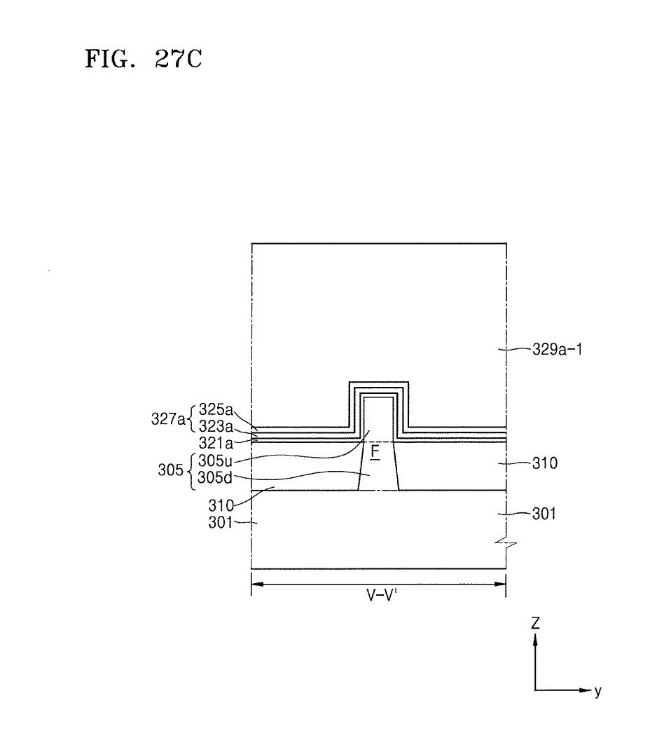

Referring to FIGS. 27A to 27C, after the formation of the lower metal layers 327a and 327b, metal layers 329a-1 and 329b-1 may be formed on the lower metal layers 327a and 327b, respectively. The metal layers 329a-1 and 329b-1 may have a large thickness so as to completely fill the remaining gap between the spacers 330. In an implementation, the metal layers 329a-1 and 329b-1 may be formed of, e.g., TiN. Meanwhile, as illustrated in the drawing, a height of the metal layer 329a-1 formed in the first region A may be greater than a height of the metal layer 329b-1 formed in the second region B by a loading effect. In an implementation, the loading effect may be prevented from occurring by forming the metal layers 329a-1 and 329b-1 to have a sufficiently large thickness or by adjusting components thereof.

After the formation of the metal layers 329a-1 and 329b-1, an upper surface of the interlayer insulating layer 340 may be exposed through a planarization process such as a CMP process. Through the planarization process, upper metal layers 329a and 329b (which are electrically separated from each other) may be formed. Gate structures 120a and 120b, e.g., the same as illustrated in FIG. 10A may be formed by forming the upper metal layers 329a and 329b. Then, a semiconductor device or a semiconductor package including a fin structure may be completed by performing subsequent semiconductor processes.

According to the method of manufacturing the semiconductor device in the present embodiment, a height of the remaining sacrificial layer may be uniformly maintained by removing the sacrificial layer to a uniform thickness or by a same amount regardless of a pattern density, through a UV irradiation etching method. Thus, a height of a lower metal layer may also be uniformly maintained. Therefore, an electrical characteristic of a transistor of the fin structure including a gate structure including such a lower metal layer may be uniformly maintained. For example, a threshold voltage of the transistor of the fin structure formed with the gate structure including the lower metal layer having the buried U-shaped structure may be changed depending on a length of a gate, and uniformity in which transistors having the same length have the same threshold voltage may be maintained.

According to the semiconductor device and the method of manufacturing the same in accordance with the embodiments, due to a lower metal layer having a buried U-shaped structure, transistors having various threshold voltages in which each threshold voltage is uniform and a semiconductor device including the transistors, for example, a logic device, may be easily implemented.

Further, according to the method of manufacturing the semiconductor device in accordance with the embodiments, as a sacrificial layer is removed with a uniform thickness regardless of a pattern density through a UV irradiation etching method, a height of the remaining sacrificial layer may be uniformly maintained, thereby also uniformly maintaining a height of a lower metal layer having a U-shaped structure. Therefore, a threshold voltage of a transistor formed with a gate structure including such a lower metal layer having the U-shaped structure may be changed depending on a length of a gate, and uniformity in which transistors have the same threshold voltage with respect to the same gate length may be maintained.

Furthermore, according to the method of manufacturing the semiconductor device in accordance with the embodiments, respective corresponding layers of a first gate structure and a second gate structure may be simultaneously formed through a single process. Therefore, in implementing a semiconductor device including transistors having various threshold voltages, the method may be advantageous in cost and manufacturing process aspects.

The embodiments may provide a semiconductor device in which various threshold voltages are implemented by changing a shape and size of a gate structure.

The embodiments may provide a semiconductor device including at least two transistors having different threshold voltages based on gate structures having different gate lengths.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1-14. (canceled)

15. A method of manufacturing a semiconductor device, the method comprising:
forming a dummy gate structure extending in one direction on a substrate;
forming spacers at both sidewalls of the dummy gate structure;
forming an interlayer insulating layer covering the substrate and a result on the substrate, and planarizing the interlayer insulating layer to expose an upper surface of the dummy gate structure;
removing the dummy gate structure, and sequentially forming a high-k dielectric layer, at least one metal layer, and a sacrificial layer on a portion in which the dummy gate structure is removed and on the interlayer insulating layer;
leaving a portion of the sacrificial layer between the spacers by etching the sacrificial layer through ultraviolet (UV) irradiation, and exposing the at least one metal layer on side surfaces of the spacers and on the interlayer insulating layer;
etching and removing portions of the exposed at least one metal layer and the high-k dielectric layer except for the portions covered by the sacrificial layer;
removing the sacrificial layer, and forming a lower metal layer having the at least one metal layer, of which a cross section is buried as a U-shaped structure; and
forming an upper metal layer on the lower metal layer and forming a gate structure.

16. The method as claimed in claim 15, wherein:
a first region and a second region are defined on the substrate;
forming the dummy gate structure includes:
forming a first dummy gate structure in the first region and having a first gate length defined as a distance between a source and a drain, and
forming a second dummy gate structure in the second region and having a second gate length which is at least two times the first gate length;
forming the lower metal layer includes forming a first lower metal layer in the first region and forming a second lower metal layer in the second region; and
forming the gate structure includes:
forming a first gate structure in the first region and having the first gate length by forming a first upper metal layer on the first lower metal layer, and
forming a second gate structure in the second region and having the second gate length by forming a second upper metal layer on the second lower metal layer.

17. The method as claimed in claim 16, wherein:
a thickness of the sacrificial layer that is removed through the UV irradiation in the first region is substantially identical to a thickness of the sacrificial layer that is removed through the UV irradiation in the second region; and
heights of protruding portions at both side surfaces of the second lower metal layer from an upper surface of the substrate are less than or equal to heights of protruding portions at both side surfaces of the first lower metal layer therefrom.

18. The method as claimed in claim 15, wherein, after the etching of the sacrificial layer through the UV irradiation, the at least one metal layer is maintained to have an identical thickness and profile before the etching of the sacrificial layer.

19. The method as claimed in claim 15, wherein the at least one metal layer is formed to have any type of a first type including a TaN layer, a second type including a TaN layer and a TiN layer, and a third type including a first TiN layer, a TaN layer, and a second TiN layer.

20. The method as claimed in claim 15, wherein:
the upper metal layer is formed of TiN; and
forming the gate structure includes planarizing the upper metal layer after coating the upper metal layer.

21. The method as claimed in claim 15, wherein the sacrificial layer is formed of a spin on hardmask.

22. The method as claimed in claim 15, wherein the sacrificial layer is formed at a temperature in a range of 150° C. to 300° C.

23. The method as claimed in claim 15, wherein the UV irradiation includes performing a baking process at a temperature in a range of 150° C. to 300° C. with power in a range of 1 W to 1,000 W.

24. The method as claimed in claim 15, further comprising, prior to forming the dummy gate structure, forming a trench by etching the substrate, forming a device isolation layer by filling a lower portion of the trench with an insulating material, and forming at least one fin protruding from the device isolation layer and extending in a first direction,
wherein the dummy gate structure has a structure extending in a second direction perpendicular to the first direction and covering a portion of the fin.

25. A method of manufacturing a semiconductor device, the method comprising:
forming a trench by etching a substrate, forming a device isolation layer by filling a lower portion of the trench with an insulating material, and forming at least one fin protruding from the device isolation layer and extending in a first direction;
forming a dummy gate structure extending in a second direction perpendicular to the first direction, covering a portion of the fin, and having a gate length defined as a distance between a source and a drain;
forming spacers that extend in the second direction and that cover the portion of the fin on both side surfaces of the dummy gate structure;
forming an interlayer insulating layer that covers the substrate and a result on the substrate, and planarizing the interlayer insulating layer to expose an upper surface of the dummy gate structure;
removing the dummy gate structure, and sequentially forming a high-k dielectric layer, at least one metal layer, and a sacrificial layer on a portion in which the dummy gate structure is removed and on the interlayer insulating layer;
leaving a portion of the sacrificial layer between the spacers by etching the sacrificial layer through ultraviolet (UV) irradiation, and exposing the at least one metal layer on side surfaces of the spacers and on the interlayer insulating layer;
etching and removing portions of the exposed at least one metal layer and the high-k dielectric layer except for the portions covered by the sacrificial layer;
removing the sacrificial layer, and forming a lower metal layer having the at least one metal layer, of which a cross section is buried as a U-shaped structure; and
forming an upper metal layer on the lower metal layer and forming a gate structure.

26. The method as claimed in claim 25, wherein:
a first region and a second region are defined on the substrate;
forming the dummy gate structure includes:
forming a first dummy gate structure in the first region and having a first gate length, and
forming a second dummy gate structure in the second region and having a second gate length that is at least two times the first gate length;
forming the lower metal layer includes:
forming a first lower metal layer in the first region, and
forming a second lower metal layer in the second region; and
forming the gate structure includes:
forming a first gate structure in the first region and having the first gate length by forming a first upper metal layer on the first lower metal layer, and
forming a second gate structure in the second region and having the second gate length by forming a second upper metal layer on the second lower metal layer.

27. The method as claimed in claim 26, wherein:
a thickness of the sacrificial layer that is removed through the UV irradiation in the first region is substantially identical to a thickness of the sacrificial layer that is removed through the UV irradiation in the second region; and
heights of protruding portions at both side surfaces of the second lower metal layer from an upper surface of the fin are less than or equal to heights of protruding portions at both side surfaces of the first lower metal layer therefrom.

28. The method as claimed in claim 25, wherein:
the at least one metal layer is formed to have any type of a first type including a TaN layer, a second type including a TaN layer and a TiN layer, and a third type including a first TiN layer, a TaN layer, and a second TiN layer; and
the upper metal layer is formed of TiN.

29. The method as claimed in claim 25, wherein:
forming the gate structure includes forming at least three gate structures having different gate lengths; and
at least three transistors formed with the at least three gate structures have different threshold voltages.

30. A method of manufacturing a semiconductor device, the method comprising:
forming at least two dummy gate structures on a substrate, one dummy gate structure of the at least two dummy gate structures having a width that is different from a width of another dummy gate structure of the dummy gate structures;
forming spacers at sidewalls of the at least two dummy gate structures;
forming an interlayer insulating layer on the substrate having the spacers thereon;
removing the at least two dummy gate structures to form at least two gate trenches;
sequentially forming a high-k dielectric layer, at least one lower metal layer, and a sacrificial layer on the substrate and in the at least two gate trenches;
partially removing the sacrificial layer by etching the sacrificial layer through ultraviolet (UV) irradiation such that a portion of the sacrificial layer remains in the at least two gate trenches;
etching and removing portions of the at least one lower metal layer and the high-k dielectric layer that are uncovered by the sacrificial layer in the at least two gate trenches such that a structure having a U-shaped cross section remains in at least two gate trenches;
removing the sacrificial layer; and
forming an upper metal layer on the at least one lower metal layer such that at least two gate structures are respectively formed in the at least two gate trenches.

31. The method as claimed in claim 30, wherein at least one of the gate structures has a gate length that is different from a gate length of another one of the at least two gate structures.

32. The method as claimed in claim 30, wherein a portion of the sacrificial layer overlying one gate trench of the at least two gate trenches has a height from the substrate that is different from that of a portion of the sacrificial layer overlying another gate trench of the at least two gate trenches.

33. The method as claimed in claim 32, wherein a thickness of the sacrificial layer that is partially removed through the UV irradiation at the one gate trench of the at least two gate trenches is substantially identical to a thickness of the sacrificial layer that is removed through the UV irradiation at the other gate trench of the at least two gate trenches.

34. The method as claimed in claim 32, wherein a height from the substrate of a protruding portion of the at least one lower metal layer in the one gate trench of the at least two gate trenches is different from a height of a protruding portion of the at least one lower metal layer in the other gate trench of the at least two gate trenches.
